(19) United States
(12) Patent Application Publication
(10) Pub. No.: US 2022/0384673 A1
(43) Pub. Date: Dec. 1, 2022

(54) LIGHT EMITTING ELEMENT AND METHOD FOR MANUFACTURING THE SAME

(71) Applicant: Samsung Display Co., LTD., Yongin-si (KR)

(72) Inventors: Ji Song Chae, Yongin-si (KR); Joo Hee Lee, Asan-si (KR); Jin Hyuk Jang, Hwaseong-si (KR); Sang Ho Jeon, Hwaseong-si (KR); Si Sung Kim, Seoul (KR); Dong Eon Lee, Hwaseong-si (KR); Hyung Seok Kim, Hwaseong-si (KR); Jong Jin Lee, Seongnam-si (KR)

(73) Assignee: Samsung Display Co., LTD., Yongin-si (KR)

(21) Appl. No.: 17/580,059

(22) Filed: Jan. 20, 2022

(30) Foreign Application Priority Data
May 28, 2021 (KR) 10-2021-0068920

(51) Int. Cl. H01L 33/00; H01L 33/02

(52) U.S. Cl. CPC H01L 33/0095; H01L 33/025; H01L 33/007; H01L 25/167

(57) ABSTRACT

A method for manufacturing a light emitting element includes forming a first semiconductor structure including a first semiconductor layer doped with a first conductivity type dopant disposed on a base substrate, a light emitting layer disposed on the first semiconductor layer, and a second semiconductor layer disposed on the light emitting layer and doped with a second conductivity type dopant; forming a second semiconductor structure spaced apart from another second semiconductor structure on the base substrate by etching the first semiconductor structure in a direction perpendicular to a surface of the base substrate; and activating a second conductivity type dopant in the second semiconductor layer of the second semiconductor structure to form a light emitting element core.

### CROSS-REFERENCE TO RELATED APPLICATION(S)

This application claims priority to and the benefit of Korean Patent Application No. 10-2021-0068920 under 35 U.S.C. § 119, filed on May 28, 2021, in the Korean Intellectual Property Office (KIPO), the entire contents of which are incorporated herein by reference.

### BACKGROUND

### 1. Technical Field

The disclosure relates to a light emitting element and a method for manufacturing the same.

### 2. Description of the Related Art

The importance of display devices has steadily increased with the development of multimedia technology. In response thereto, various types of display devices such as an organic light emitting display (OLED), a liquid crystal display (LCD) and the like have been used.

A display device is a device for displaying an image, and includes a display panel, such as an organic light emitting display panel or a liquid crystal display panel. The display panel may include a light emitting element, and the light emitting element may be a light emitting diode (LED). The light emitting diode includes an organic light emitting diode (OLED) that uses an organic material as a light emitting material, and an inorganic light emitting diode that uses an inorganic material as a light emitting material.

### SUMMARY

Aspects of the disclosure provide a method for manufacturing a light emitting element that minimizes surface damage of first and second semiconductor layers of the light emitting element by adjusting the Fermi level of the first and second semiconductor layers.

Aspects of the disclosure also provide a light emitting element with improved luminous efficiency by minimizing surface damage thereof.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment of the disclosure, there is provided a method for manufacturing a light emitting element, comprising forming a first semiconductor structure including a first semiconductor layer doped with a first conductivity type dopant disposed on a base substrate, a light emitting layer disposed on the first semiconductor layer, and a second semiconductor layer disposed on the light emitting layer and doped with a second conductivity type dopant; forming a second semiconductor structure spaced apart from another second semiconductor structure on the base substrate by etching the first semiconductor structure in a direction perpendicular to a surface of the base substrate; and activating a second conductivity type dopant in the second semiconductor layer of the second semiconductor structure to form a light emitting element core.

The activating of the second conductivity type dopant may comprise performing an annealing process.

The annealing process may comprise performing heat treatment on the second semiconductor layer in a temperature range of about 450° C. to about 750° C.

The annealing process may comprise performing heat treatment on the second semiconductor layer in a temperature range of about 170° C. to about 550° C.

The first semiconductor structure may further comprise an element electrode layer disposed on the second semiconductor layer.

The first conductivity type may be an n type, and the second conductivity type may be a p type.

A hydrogen concentration of the second semiconductor layer of the light emitting element core may have a concentration gradient increasing from a side surface of the second semiconductor layer toward a center of the second semiconductor layer.

The hydrogen concentration of the second semiconductor layer of the light emitting element core may be about 1×10¹⁹/cm3 or less.

A doping amount of the second conductivity type dopant doped into the second semiconductor layer of the first semiconductor structure may be in a range of about 1.0×10¹⁹/cm3 to about 1.26×10¹⁹/cm3.

A side surface of the first semiconductor layer of the second semiconductor structure and a side surface of the second semiconductor layer of the second semiconductor structure may be aligned in a line.

According to another embodiment of the disclosure, there is provided a method for manufacturing a light emitting element, comprising forming a first semiconductor structure including a first semiconductor layer doped with a first conductivity type dopant disposed on a base substrate, a light emitting layer disposed on the first semiconductor layer, and a second semiconductor layer disposed on the light emitting layer and doped with a second conductivity type dopant; activating a second conductivity type dopant in the second semiconductor layer of the first semiconductor structure to form a second semiconductor structure; and forming a plurality of light emitting element cores spaced apart from each other on the base substrate by etching the second semiconductor structure in a direction perpendicular to a surface of the base substrate. A doping amount of the second conductivity type dopant doped into the second semiconductor layer of the first semiconductor structure may be about 1.0×10¹⁹/cm³ or less.

The activating of the second conductivity type dopant may comprise performing heat treatment on the second semiconductor layer in a temperature range of about 450° C. to about 750° C.

The first conductivity type may be an n type, and the second conductivity type may be a p type.

An amount of the second conductivity type dopant in the second semiconductor layer of the light emitting element core may be about 1.0×10¹⁹/cm³ or less.

A side surface of the first semiconductor layer of the light emitting element core and a side surface of the second semiconductor layer of the light emitting element core may be aligned in a line.

According to still another embodiment of the disclosure, there is provided a light emitting element, comprising: a first semiconductor layer having a first conductivity type; a second semiconductor layer disposed on the first semiconductor layer and having a second conductivity type; and a light emitting layer disposed between the first semiconductor layer and the second semiconductor layer. The light emitting element may extend in a direction, a side surface of the first semiconductor layer and a side surface of the second semiconductor layer may be aligned in a line, and in a cross-sectional view perpendicular in the direction to the second semiconductor layer, a concentration of hydrogen included in the second semiconductor layer may have a concentration gradient increasing from a side surface of the second semiconductor layer to a center of the second semiconductor layer.

A hydrogen concentration of the second semiconductor layer may be about 1×10¹⁹/cm³ or less.

The first conductivity type may be an n type, and the second conductivity type may be a p type.

The first semiconductor layer may be doped with a first conductivity type dopant, the second semiconductor layer may be doped with a second conductivity type dopant, and an amount of the second conductivity type dopant doped into the second semiconductor layer may be about 1.0×10¹⁹/cm³ or less.

An angle between the side surface of the second semiconductor layer and the side surface of the first semiconductor layer may be in a range of about 200 or less.

In the method for manufacturing a light emitting element according to an embodiment, a difference in Fermi level between a first semiconductor material layer and a second semiconductor material layer may be minimized, and a difference in etching rate therebetween by the same etchant may be minimized by performing a second etching step without activating a second conductivity type dopant doped into the second semiconductor material layer. Accordingly, surface damage regions of the first and second semiconductor material layers may be efficiently removed. Accordingly, it is possible to prevent a decrease in luminous efficiency of the light emitting element manufactured by the manufacturing process according to the embodiment.

In addition, in the method for manufacturing a light emitting element according to another embodiment, a difference in Fermi level between a first semiconductor material layer and a second semiconductor material layer may be minimized and a difference in etching rate therebetween by the same etchant may be minimized by adjusting the doping amount of the second conductivity type dopant doped into the second semiconductor material layer. Accordingly, surface damage regions of the first and second semiconductor material layers may be efficiently removed. Accordingly, it is possible to prevent a decrease in luminous efficiency of the light emitting element manufactured by the manufacturing process according to the embodiment.

However, the effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a light emitting element according to an embodiment;

FIG. 2 is a schematic cross-sectional view of a light emitting element according to an embodiment;

FIGS. 3 to 10 are schematic cross-sectional views of each process step showing a part of one example of a manufacturing process of a light emitting element according to an embodiment;

FIG. 11 is a graph illustrating formation energy according to the Fermi level;

FIGS. 12 to 15 are schematic cross-sectional views of each process step showing a part of an example of a manufacturing process of a light emitting element according to an embodiment;

FIG. 16 is a schematic diagram schematically illustrating an area of a surface damage region of a second semiconductor layer of a light emitting element and a shape thereof according to over-etching;

FIG. 17 is a graph illustrating the efficiency of the light emitting element shown in FIG. 16 according to over-etching of the light emitting element;

FIGS. 18A and 18B are images illustrating examples of a light emitting element formed according to a manufacturing process of the light emitting element;

FIGS. 19 to 23 are schematic cross-sectional views of process steps illustrating a part of another example of a manufacturing process of a light emitting element according to an embodiment;

FIG. 24 is a schematic cross-sectional view of a light emitting element according to another embodiment;

FIG. 25 is a schematic cross-sectional view of a light emitting element according to still another embodiment;

FIG. 26 is a schematic plan view of a display device according to an embodiment;

FIG. 27 is a schematic plan layout view illustrating one pixel of a display device according to an embodiment; and

FIG. 28 is a schematic cross-sectional view illustrating an example taken along line I-I′ of FIG. 27.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

It will be understood that the terms “contact,” “connected to,” and “coupled to” may include a physical and/or electrical contact, connection, or coupling, and vice versa.

The phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the drawings.

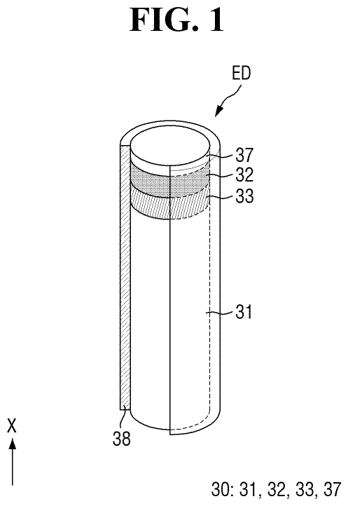

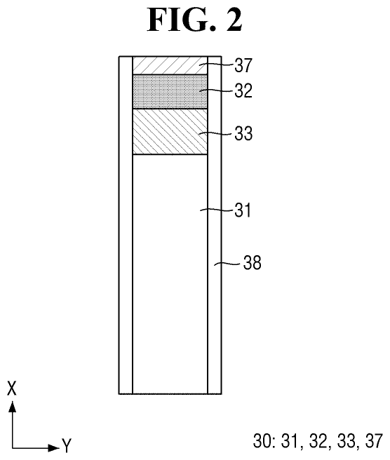

FIG. 1 is a schematic perspective view of a light emitting element according to an embodiment. FIG. 2 is a schematic cross-sectional view of a light emitting element according to an embodiment.

Referring to FIGS. 1 and 2, a light emitting element ED which is a particulate element may have a rod or cylindrical shape having a predetermined aspect ratio. The light emitting element ED may extend in a direction X, the length of the light emitting element ED in its extension direction (or longitudinal direction) X may be greater than the diameter of the light emitting element ED, and the aspect ratio thereof may be about 6:5 to about 100:1, but the disclosure is not limited thereto. Hereinafter, in the drawings illustrating the shape of the light emitting element ED, the terms of a direction X, the extension direction X of the light emitting element ED, and the longitudinal direction X of the light emitting element ED may be used interchangeably.

The light emitting element ED may have a size of a nanometer scale (equal to or greater than about 1 nm and less than about 1 μm) to a micrometer scale (equal to or greater than about 1 μm and less than about 1 mm). In an embodiment, both the diameter and length of the light emitting element ED may be on a nanometer scale, or on a micrometer scale. In some embodiments, the diameter of the light emitting element ED may be on a nanometer scale, while the length of the light emitting element ED may be on a micrometer scale. In some embodiments, some of the light emitting elements ED may have a diameter and/or length on a nanometer scale, while some others of the light emitting elements ED may have a diameter and/or length on a micrometer scale.

In an embodiment, the light emitting element ED may be an inorganic light-emitting diode (LED). The inorganic light emitting diode may include semiconductor layers. For example, the inorganic light emitting diode may include a first conductivity type (e.g., n-type) semiconductor layer, a second conductivity type (e.g., p-type) semiconductor layer, and an active semiconductor layer interposed therebetween. The active semiconductor layer may receive holes and electrons from the first conductivity type semiconductor layer and the second conductivity type semiconductor layer, respectively, and the holes and electrons that have reached the active semiconductor layer may be coupled or combined to emit light.

The light emitting element ED may include a light emitting element core 30 and an element insulating film 38.

The light emitting element core 30 may extend in the direction X. The light emitting element core 30 may have a rod or cylindrical shape. However, the disclosure is not limited thereto, and the light emitting element core 30 may have a shape of a polygonal prism such as a cube, a cuboid, or a hexagonal prism, or may extend in the direction X with an outer surface partially inclined.

The light emitting element core 30 may include a first semiconductor layer 31, a second semiconductor layer 32, a light emitting layer 33, and an element electrode layer 37. The first semiconductor layer 31, the light emitting layer 33, the second semiconductor layer 32, and the element electrode layer 37 may be sequentially stacked in the direction X, which is the longitudinal direction of the light emitting element core 30.

The first semiconductor layer 31 may be doped with a first conductivity type dopant. The first conductivity type may be an n type, and the first conductivity type dopant may be Si, Ge, Sn, or the like. For example, the first semiconductor layer 31 may be an n-type semiconductor. In an embodiment, the first semiconductor layer 31 may be n-GaN doped with n-type Si.

The second semiconductor layer 32 may be spaced apart from the first semiconductor layer 31 with the light emitting layer 33 interposed therebetween. The second semiconductor layer 32 may be doped with a second conductivity type dopant. The second conductivity type may be a p type, and the second conductivity type dopant may be Mg, Zn, Ca, or Ba, or the like. For example, the second semiconductor layer 32 may be a p-type semiconductor. In an embodiment, the second semiconductor layer 32 may be p-GaN doped with p-type Mg.

Although FIGS. 1 and 2 illustrate that the first semiconductor layer 31 and the second semiconductor layer 32 are configured as single layers, the disclosure is not limited thereto. Depending on the material of the light emitting layer 33, the first semiconductor layer 31 and the second semiconductor layer 32 may further include a larger number of layers, such as a cladding layer or a tensile strain barrier reducing (TSBR) layer.

The light emitting layer 33 may be disposed between the first semiconductor layer 31 and the second semiconductor layer 32. The light emitting layer 33 may include a material having a single or multiple quantum well structure. The light emitting layer 33 may emit light by coupling of electron-hole pairs according to an electrical signal applied through the first semiconductor layer 31 and the second semiconductor layer 32. For example, in case that the light emitting layer 33 emits light of a blue wavelength band, a material such as AlGaN, InGaN, or AlGaInN may be included.

In some embodiments, the light emitting layer 33 may have a structure in which semiconductor materials having large band gap energy and semiconductor materials having small band gap energy are alternately stacked, and may include other group III to V semiconductor materials according to the wavelength band of emitted light.

Light emitted from the light emitting layer 33 may be emitted not only from both end surfaces of the light emitting element ED in the direction X, which is its longitudinal direction, but also from the side surface of the light emitting element ED. The direction of the light emitted from the light emitting layer 33 is not limited to a direction.

The element electrode layer 37 may be disposed on the second semiconductor layer 32. The second semiconductor layer 32 may be disposed between the element electrode layer 37 and the light emitting layer 33. For example, the first semiconductor layer 31, the light emitting layer 33, the second semiconductor layer 32, and the element electrode layer 37 may be sequentially stacked in the direction X. The element electrode layer 37 may be an ohmic contact electrode. However, the element electrode layer 37 is not limited thereto, and may be a Schottky contact electrode.

In case that both ends of the light emitting element ED are electrically connected to electrodes in order to apply an electrical signal to the first semiconductor layer 31 and the second semiconductor layer 32, the element electrode layer 37 may be disposed between the second semiconductor layer 32 and the electrode to reduce resistance. The element electrode layer 37 may include at least one of aluminum (Al), titanium (Ti), indium (In), gold (Au), silver (Ag), indium tin oxide (ITO), indium zinc oxide (IZO), or indium tin zinc oxide (ITZO). The element electrode layer 37 may include a semiconductor material doped with an n-type or p-type dopant.

The element insulating film 38 may be disposed to surround the side surface of the light emitting element core 30. Specifically, the element insulating film 38 may be disposed to surround the side surfaces of semiconductor layers and the element electrode layer 37 included in the light emitting element core 30. For example, the element insulating film 38 may be disposed to surround at least the side surface of the light emitting layer 33, and may extend in the direction X which is the extension direction of the light emitting element ED. The element insulating film 38 may function to protect the members. The element insulating film 38 may be formed to surround the side surfaces of the above members, while exposing both end surfaces of the light emitting element ED in its longitudinal direction X.

The element insulating film 38 may function to protect the first semiconductor layer 31, the second semiconductor layer 32, and the light emitting layer 33. Since the element insulating film 38 includes a material having an insulating property, an electrical short circuit that may occur in case that the light emitting layer 33 directly contacts an electrode that transmits an electrical signal to the light emitting element ED, may be prevented.

In the drawings, it is illustrated that the element insulating film 38 is formed to extend in the longitudinal direction X of the light emitting element ED and cover from the side surface of the first semiconductor layer 31 to the side surface of the element electrode layer 37, but the disclosure is not limited thereto. For example, the element insulating film 38 may cover only the side surfaces of some semiconductor layers including the light emitting layer 33, or may cover a part of the side surface of the element electrode layer 37 while exposing the other part of the side surface of the element electrode layer 37. Although the drawings illustrate that the element insulating film 38 is formed as a single layer, the disclosure is not limited thereto. For example, the element insulating film 38 may have a structure in which insulating layers including an insulating material are stacked.

In the light emitting element ED according to the embodiment, the side surface of the first semiconductor layer 31, the side surface of the second semiconductor layer 32, and the side surface of the light emitting layer 33 may be aligned in a line. The side surface of the first semiconductor layer 31 and the side surface of the second semiconductor layer 32 may be positioned on the same plane.

As will be described below, in the manufacturing process (or fabricating process) of the light emitting element ED according to an embodiment, the second semiconductor layer 32 may be formed by etching a semiconductor layer doped with the second conductivity type dopant so as to have the shape of the light emitting element core 30, and then performing a step of activating the second conductivity type dopant. In an embodiment in which the second conductivity type dopant includes Mg, the step of activating the second conductivity type dopant may be performed by decomposing Mg—H bonds of the second semiconductor layer 32 by an annealing process in which heat is applied to the second semiconductor layer 32. After etching the semiconductor layer doped with the second conductivity type dopant, the step of activating the second conductivity type dopant is performed to form the second semiconductor layer 32, so that the hydrogen content of the second semiconductor layer 32 may have a specific distribution.

The second semiconductor layer 32 may include hydrogen (H) and the second conductivity type dopant. The content of the second conductivity type dopant included in the second semiconductor layer 32 may be in a range of about 1.0×10¹⁹/cm³ to about 1.26×10¹⁹/cm³, and the content of the hydrogen included in the second semiconductor layer 32 may be in a range of about 1×10¹⁹/cm³ or less. In a cross-sectional view of the second semiconductor layer 32 taken in a direction Y perpendicular to the longitudinal direction X of the light emitting element ED, the distribution of the hydrogen content of the second semiconductor layer 32 may increase from the surface of the second semiconductor layer 32 toward the center thereof. A detailed description of the hydrogen content and the hydrogen content distribution of the second semiconductor layer 32 will be given in detail through the fabricating process of the light emitting element ED to be described below.

As will be described below, in the fabricating process of the light emitting element ED according to some embodiments, the second semiconductor layer 32 may be formed by activating a semiconductor layer doped with the second conductivity type dopant, and then etching the semiconductor layer so as to have the shape of the light emitting element core 30. On the other hand, in order to adjust the Fermi level of the first semiconductor layer 31 and the second semiconductor layer 32 to have similar etching rates with respect to the same etchant, the doping amount of the second conductivity type dopant doped into the second semiconductor layer 32 may be different from the doping amount of the second conductivity type dopant doped in the fabricating process of the light emitting element ED according to the embodiment. In this case, the doping amount of the second conductivity type dopant included in the second semiconductor layer 32 of the light emitting element ED may be smaller than the doping amount of the second conductivity type dopant included in the second semiconductor layer 32 of the light emitting element ED according to the embodiment. In the light emitting element ED according to some embodiments, the content of the second conductivity type dopant included in the second semiconductor layer 32 may be in a range of about 1.0×10¹⁹/cm³ or less.

Hereinafter, a fabricating process of the light emitting element ED according to an embodiment will be described in order with reference to other drawings.

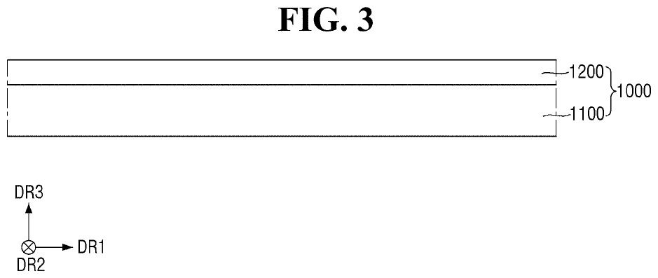

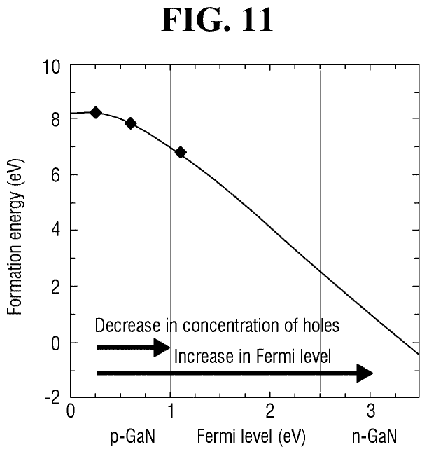

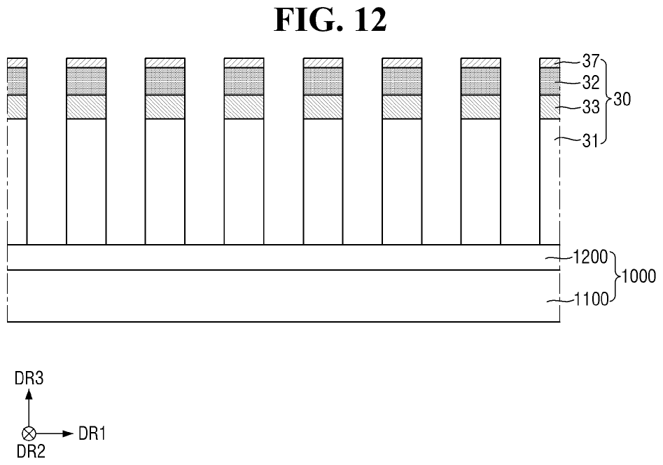

FIGS. 3 to 10 are schematic cross-sectional views of each process step illustrating a part of an example of a fabricating process of a light emitting element according to an embodiment. FIG. 11 is a graph illustrating formation energy according to the Fermi level. FIGS. 12 to 15 are schematic cross-sectional views of each process step illustrating a part of an example of a fabricating process of a light emitting element according to an embodiment.

Hereinafter, a first direction DR1, a second direction DR2, and a third direction DR3 are defined in drawings of an embodiment for describing the fabricating process of the light emitting element ED. The first direction DR1 and the second direction DR2 may be perpendicular to each other, and the third direction DR3 may be a direction perpendicular to a plane on which the first direction DR1 and the second direction DR2 are placed.

The third direction DR3 may be a direction parallel to the direction X, which is the extension direction of the light emitting element ED formed on a lower substrate 1000. In the embodiment describing the fabricating process of the light emitting element ED, unless otherwise stated, “upward” indicates a side of the third direction DR3, e.g., a direction in which the semiconductor layers of the light emitting element ED are stacked from a surface (or top surface) of the lower substrate 1000, and “top surface” indicates a surface toward a side of the third direction DR3. Further, the term “downward” refers to the other side of the third direction DR3, and the term “bottom surface” refers to a surface toward the other side of the third direction DR3.

First, referring to FIG. 3, the lower substrate 1000 is prepared.

Specifically, the lower substrate 1000 may include a base substrate 1100 and a buffer material layer 1200 disposed on the base substrate 1100.

The base substrate 1100 may include a sapphire substrate (AlₓO_{y}) or a transparent substrate such as glass. However, the disclosure is not limited thereto, and the base substrate 1100 may include a conductive substrate such as a GaN, SiC, ZnO, Si, GaP and GaAs substrate. In an embodiment, the base substrate 1100 may be a sapphire substrate (AlₓO_{y}).

Semiconductor layers may be formed on the base substrate 1100. The semiconductor layers may be formed by growing a seed crystal on the base substrate 1100 by an epitaxial method. The semiconductor layer may be formed using electron beam deposition, physical vapor deposition (PVD), chemical vapor deposition (CVD), plasma laser deposition (PLD), dual-type thermal evaporation, sputtering, metal organic chemical vapor deposition (MOCVD), or the like.

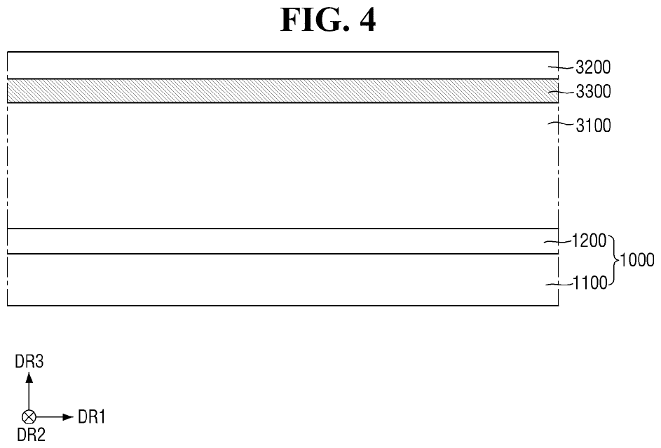

The buffer material layer 1200 may be formed on a surface (or top surface) of the base substrate 1100. The buffer material layer 1200 may reduce a lattice constant difference between the base substrate 1100 and a first semiconductor material layer 3100 (see FIG. 4) to be described below. The buffer material layer 1200 may include an undoped semiconductor. The buffer material layer 1200, and the first semiconductor material layer 3100 to be described below may include the same material, but the buffer material layer 1200 may include a material not doped with the first conductivity type dopant or the second conductivity type dopant, e.g., an n-type or p-type dopant. Although the drawing shows that the buffer material layer 1200 is stacked as a single layer, the buffer material layer 1200 may be formed of (or include) layers. The buffer material layer 1200 may be omitted depending on the type of the base substrate 1100.

Next, referring to FIG. 4, the semiconductor layers are formed on the lower substrate 1000.

Specifically, the semiconductor layers in which the first semiconductor material layer 3100, a light emitting material layer 3300, and a second semiconductor material layer 3200 are sequentially stacked are formed on the lower substrate 1000. The first semiconductor material layer 3100 may be entirely formed on the top surface of the lower substrate 1000, the light emitting material layer 3300 may be entirely formed on the top surface of the first semiconductor material layer 3100, and the second semiconductor material layer 3200 may be entirely formed on the top surface of the light emitting material layer 3300.

The first semiconductor material layer 3100 may correspond to the first semiconductor layer 31 of the above-described light emitting element ED, and the light emitting material layer 3300 may correspond to the light emitting layer 33 of the above-described light emitting element ED. Accordingly, the first semiconductor material layer 3100 and the first semiconductor layer 31 may include the same material, and the light emitting material layer 3300 and the light emitting layer 33 may include the same material. For example, the first semiconductor material layer 3100 may be doped with the first conductivity type dopant, and the first conductivity type may be an n type. In an embodiment, the first semiconductor material layer 3100 may be n-GaN doped with n-type Si.

The second semiconductor material layer 3200 may correspond to the second semiconductor layer 32, but may be in a state in which the second conductivity type dopant has not been activated. Specifically, the second semiconductor material layer 3200 may be doped with the second conductivity type dopant, the second conductivity type may be a p type, and the second conductivity type dopant may be in a state bonded to hydrogen. In an embodiment, the second semiconductor material layer 3200 may be p-GaN doped with p-type Mg, but Mg doped into the second semiconductor material layer 3200 may be in a non-activated state by combining with H. In the embodiment, the doping amount of the second conductivity type dopant doped into the second semiconductor material layer 3200 may range from about 1.0×10¹⁹/cm³ to about 1.26×10¹⁹/cm³, but the disclosure is not limited thereto.

Unless otherwise stated herein, in describing or illustrating the second semiconductor material layer, in case that the second semiconductor material layer is shaded, the second semiconductor material layer may be a semiconductor layer in which the second conductivity type dopant has been activated, and in case that the second semiconductor material layer is not shaded, the second semiconductor material layer may be a semiconductor layer in which the second conductivity type dopant has not been activated.

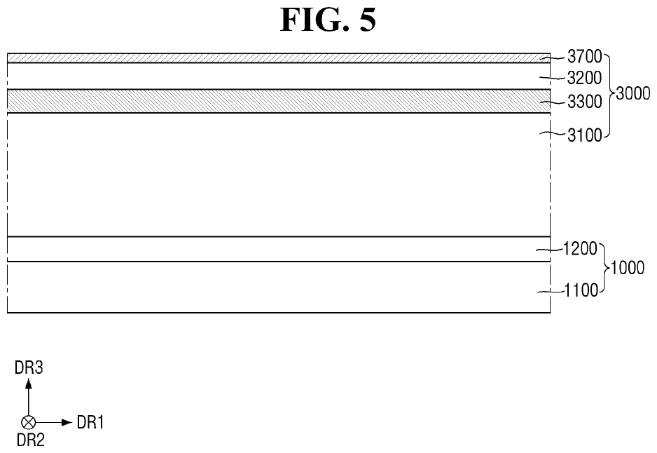

Next, referring to FIG. 5, a first semiconductor structure 3000 is formed by forming an electrode material layer 3700 on the second semiconductor material layer 3200.

Specifically, the first semiconductor structure 3000 is formed by forming the electrode material layer 3700 on the top surface of the second semiconductor material layer 3200 in which the second conductivity type dopant has been doped but not activated. The electrode material layer 3700 may be entirely formed on the top surface of the second semiconductor material layer 3200. The electrode material layer 3700 may correspond to the element electrode layer 37 of the above-described light emitting element ED. Accordingly, the electrode material layer 3700 and the element electrode layer 37 may include the same material.

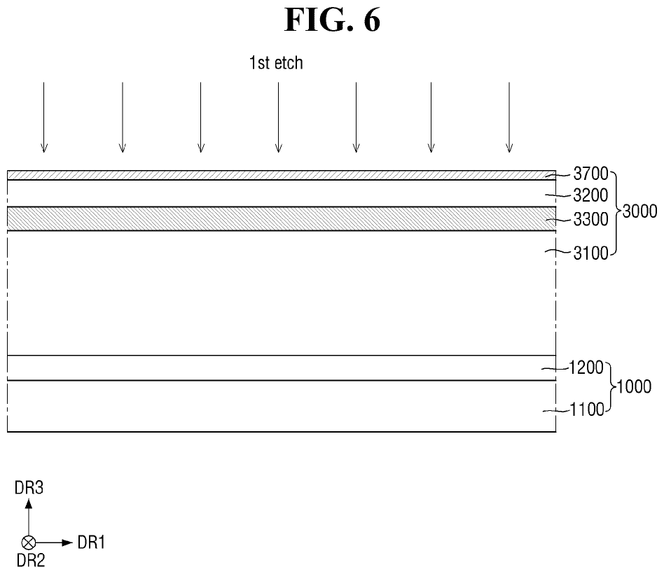

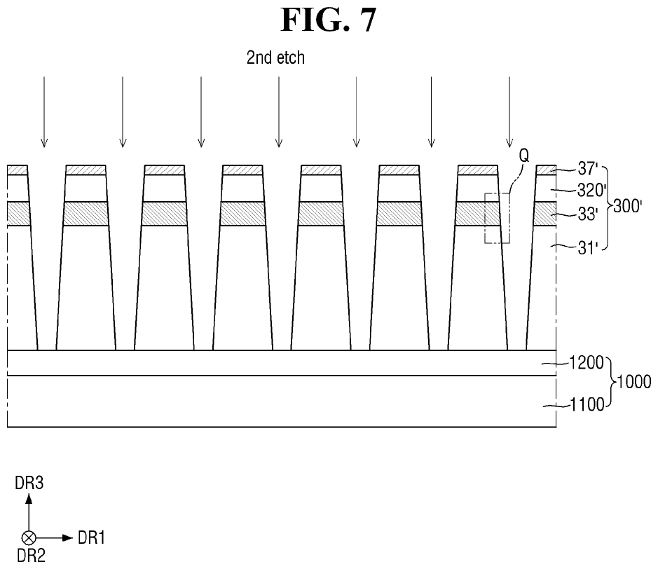

Next, referring to FIGS. 6 and 7, the first semiconductor structure 3000 is etched to form second semiconductor structures 300′ spaced apart from each other (first etching step, 1^{st} etch).

Specifically, as shown in FIG. 6, the first etching step (1^{st} etch) of etching the first semiconductor structure 3000 in a direction, e.g., in the third direction DR3, perpendicular to the top surface of the lower substrate 1000 is performed to form, as shown in FIG. 7, the second semiconductor structures 300′ spaced apart from each other.

The first semiconductor structure 3000 may be etched by a conventional patterning method. For example, the patterning method may be performed by forming an etch mask layer on the first semiconductor structure 3000 and etching the first semiconductor structure 3000 along the etch mask layer in the third direction DR3.

The first etching step (1^{st} etch) of etching the first semiconductor structure 3000 may be performed by dry etching. The first semiconductor material layer 3100, the light emitting material layer 3300, the second semiconductor material layer 3200, and the electrode material layer 3700 of the first semiconductor structure 3000 may be etched by the first etching step (1^{st} etch) performed by dry etching to form second semiconductor structures 300′ spaced apart from each other as shown in FIG. 7. In the case of dry etching, anisotropic etching may be used, so it may be suitable for vertical etching. However, the disclosure is not limited thereto, the etching etchant used for the dry etching may be Cl₂, O₂, or the like.

The second semiconductor structure 300′ may have a width decreasing toward an upper side thereof. For example, the second semiconductor structure 300′ may have a trapezoidal shape in a cross-sectional view taken in the third direction DR3. The second semiconductor structure 300′ may have an inclined side surface. The side surfaces of the first semiconductor material layer 31′, the light emitting material layer 33′, the second semiconductor material layer 320′, and the electrode material layer 37′ included in the second semiconductor structure 300′ may be arranged in a line, but may be inclined. The diameter of the first semiconductor material layer 31′ may be greater than the diameter of the second semiconductor material layer 320′.

The first semiconductor material layer 31′, the light emitting material layer 33′, the second semiconductor material layer 320′, and the electrode material layer 37′ of the second semiconductor structure 300′ may correspond to the first semiconductor material layer 3100, the light emitting material layer 3300, the second semiconductor material layer 3200, and the electrode material layer 3700 of the first semiconductor structure 3000, respectively. Accordingly, the first semiconductor material layer 31′, the light emitting material layer 33′, the second semiconductor material layer 320′, and the electrode material layer 37′ of the second semiconductor structure 300′ and the first semiconductor layer 3100, the light emitting layer 3300, the second semiconductor layer 3200, and the electrode layer 3700 of the first semiconductor structure 3000 may include a same material.

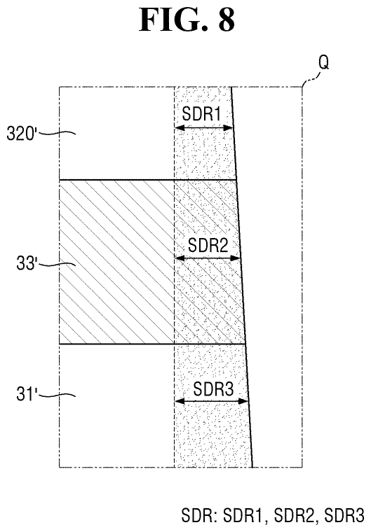

FIG. 8 is a schematic enlarged view of area Q of FIG. 7. Referring to FIG. 8, the second semiconductor structure 300′ may include a surface damage region SDR. The surface damage region SDR may be located on the surface of the second semiconductor structure 300′. The surface damage region SDR may be a region where a defect has occurred in the semiconductor material formed in the first etching step (1^{st} etch) of etching the first semiconductor structure 3000, and the defect in the semiconductor material may occur on the surface of the second semiconductor structure 300′.

The surface damage region SDR may include a first surface damage region SDR3 positioned on the outer surface of the first semiconductor material layer 31′, a second surface damage region SDR1 positioned on the outer surface of the second semiconductor material layer 320′, and a third surface damage region SDR2 positioned on the outer surface of the light emitting material layer 33′.

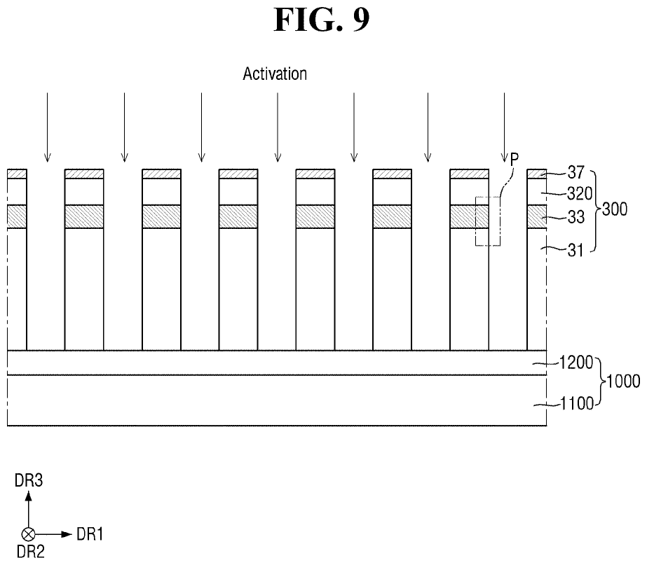

Subsequently, referring to FIGS. 7 and 9, the second semiconductor structures 300′ are etched such that the side surfaces of the semiconductor layers included in the second semiconductor structure 300′ are aligned in a line to form third semiconductor structures 300 (second etching step, 2^{nd} etch).

Specifically, as shown in FIG. 7, the second etching step (2^{nd} etch) of etching the second semiconductor structures 300′ in the third direction DR3 is performed to form, as shown in FIG. 9, the third semiconductor structures 300 whose side surfaces are perpendicular to the top surface of the lower substrate 1000.

The second etching step (2^{nd} etch) of etching the second semiconductor structures 300′ may be performed by wet etching. The side surfaces of the first semiconductor material layer 31′, the light emitting material layer 33′, the second semiconductor material layer 320′, and the electrode material layer 37′ of the second semiconductor structure 300′ may be partially etched by the second etching step (2^{nd} etch) performed by wet etching to form, as shown in FIG. 9, the third semiconductor structure 300 having a side surface perpendicular to the top surface of the lower substrate 1000. However, the disclosure is not limited thereto, and an etchant (or etching etchant) used for the wet etching may be KOH or the like.

The side surface of the third semiconductor structure 300 may be perpendicular to the top surface of the lower substrate 1000. Since the side surface of the third semiconductor structure 300 is substantially perpendicular to the lower substrate 1000, the side surfaces of the first semiconductor material layer 31′, the light emitting material layer 33, the second semiconductor material layer 320′, and the electrode material layer 3700 included in the third semiconductor structure 300 may be aligned in a line in parallel to the extension direction of the third semiconductor structure 300. In the third semiconductor structure 300, the diameter of the first semiconductor material layer 31′ may be substantially the same as the diameter of the second semiconductor material layer 320.

The first semiconductor material layer 31′, the light emitting material layer 33′, the second semiconductor material layer 320′, and the electrode material layer 37′ of the third semiconductor structure 300 may correspond to the first semiconductor material layer 3100, the light emitting material layer 3300, the second semiconductor material layer 3200, and the electrode material layer 3700 of the first semiconductor structure 3000, respectively. Accordingly, the first semiconductor material layer 31′, the light emitting material layer 33′, the second semiconductor material layer 320′, and the electrode material layer 37′ of the third semiconductor structure 300 and the first semiconductor layer 3100, the light emitting layer 3300, the second semiconductor layer 3200, and the electrode layer 3700 of the first semiconductor structure 3000 may include a same material.

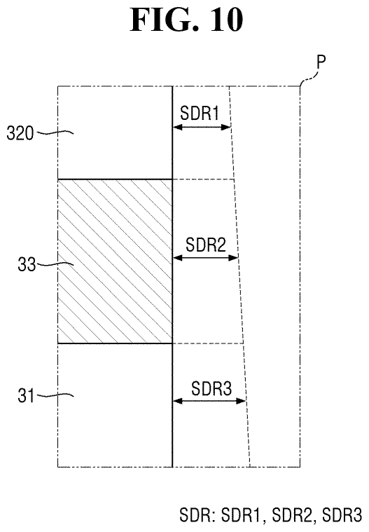

FIG. 10 is a schematic enlarged view of area P of FIG. 9. Referring to FIG. 10, the surface damage region SDR of the second semiconductor structure 300′ may be removed by the second etching step (2^{nd} etch). In an embodiment in which the second etching step (2^{nd} etch) is performed by wet etching, the surface damaged region SDR of the second semiconductor structure 300′ may be etched by the etchant (or etching etchant) used in the second etching step (2^{nd} etch) to form the third semiconductor structure 300 that does not include the surface damaged region SDR as shown in FIG. 10. Accordingly, the surface damage region SDR caused by the defect in the semiconductor material may not be present on the surface of the third semiconductor structure 300.

With respect to the etchant used in the second etching step (2^{nd} etch), in case that the difference in etching rate between the first semiconductor material layer 31′ of the second semiconductor structure 300′ and the second semiconductor material layer 320′ of the second semiconductor structure 300′ is large, the surface damage region SDR3, SDR1 of one of the first semiconductor material layer 31′ and the second semiconductor material layer 320′ may not be completely removed. In case that the surface damage region SDR remains without being completely removed (e.g., in case that the surface of the semiconductor layer has been damaged), the luminous efficiency of the light emitting element ED may be reduced due to the damaged semiconductor layer. For example, in case that the surface damage remains in the first semiconductor layer 31, injected electrons may leak, which may be a factor impairing the luminous efficiency of the light emitting element ED, and in case that the surface damage remains in the second semiconductor layer 32, the surface damage may capture holes, which may be a factor impairing the luminous efficiency of the light emitting element ED. Accordingly, with respect to the etchant used in the second etching step, a difference in etching rate between the first semiconductor material layer 31′ and the second semiconductor material layer 320′ of the second semiconductor structure 300′ to be subjected to the second etching step (2^{nd} etch) may be minimized, thereby preventing the surface damage from remaining.

In the embodiment in which the first semiconductor material layer 31′ of the second semiconductor structure 300′ includes n-GaN and the second semiconductor material layer 320′ thereof includes p-GaN, with respect to the etchant used in the second etching step (2^{nd} etch), the etching rate of the first semiconductor material layer 31′ of the second semiconductor structure 300′ and the etching rate of the second semiconductor material layer 320′ of the second semiconductor structure 300′ may be adjusted according to formation energy depending on the Fermi level of Ga.

FIG. 11 is a graph illustrating the formation energy of gallium (Ga) vacancy depending on the Fermi level, and an x-axis indicates the Fermi level and a y-axis indicates the formation energy of gallium vacancy. As shown in FIG. 11, it may be seen that the Fermi level increases from p-GaN to n-GaN, and the formation energy decreases as the Fermi level increases. Therefore, since the Fermi level of p-GaN is smaller than that of n-GaN and thus the formation energy of p-GaN is greater than that of n-GaN, the etching rate for the same etchant may be greater for n-GaN than for p-GaN. Accordingly, by minimizing the difference in Fermi level between p-GaN and n-GaN, the difference in etching rate for the same etchant may be minimized, and accordingly, the surface damage regions of the first semiconductor material layer and the second semiconductor material layer may be efficiently removed.

Referring to the graph of FIG. 11, in p-GaN, as the concentration of holes decreases, the Fermi level increases. Therefore, it may be seen that as the number of bonds between the second conductivity type dopant of p-GaN and H increases, the concentration of holes decreases, so that the Fermi level increases, thereby reducing the formation energy. Accordingly, since the formation energy of p-GaN before activating the second conductivity type dopant doped in p-GaN is higher than the formation energy of p-GaN after activating the second conductivity type dopant, it may be difficult to etch a semiconductor structure using the etchant. Accordingly, by etching the second semiconductor material layer 320′ in which the second conductivity type dopant has not been activated by the second etching step (2^{nd} etch), the difference in Fermi level between the first semiconductor material layer 31′ and the second semiconductor material layer 320′ may be minimized, thereby minimizing the difference in etching rate between the two layers. Accordingly, it is possible to efficiently prevent defects from remaining on the surface of the second semiconductor layer 32.

Referring to FIGS. 9 and 12, a step of activating the second conductivity type dopant doped into the second semiconductor material layer 320 of the third semiconductor structure 300 is performed. By the activation step of the second semiconductor material layer 320 included in the third semiconductor structure 300, as shown in FIG. 12, the light emitting element core 30 including the second semiconductor layer 32 in which the second conductivity type dopant has been activated may be formed.

The step for activating the second conductivity type dopant doped into the second semiconductor material layer 320 of the third semiconductor structure 300 is doped may include an annealing process in which heat treatment is performed within a predetermined temperature range.

In an embodiment, the heat treatment of the annealing process may be performed in a temperature range of about 450° C. to about 750° C. In an embodiment in which the second conductivity type dopant includes Mg, Mg—H bonds of the second semiconductor material layer 320 may be decomposed by heat applied by the activation step, so that the amount (or number) of holes may be increased, and the activated second semiconductor layer 32 may be formed.

In some embodiments, the heat treatment of the annealing process may be performed in a temperature range of about 170° C. to about 550° C., preferably at a temperature of about 170° C. to about 175° C. In an embodiment in which the second conductivity type dopant includes Mg, as described above, the Mg—H bonds of the second semiconductor material layer 320 may be decomposed by the heat applied by the activation step, so that the amount of holes may be increased, and the activated second semiconductor layer 32 may be formed. In this case, the second semiconductor material layer 320 may be pre-etched before the activation step, and thus the exposed surface area of the second semiconductor material layer 320 is increased in the activation step of activating the second conductivity type dopant, so that the annealing process may be performed even at a relatively low temperature to activate the second conductivity type dopant. Accordingly, deformation of the electrode layer 37 of the third semiconductor structure 300 by the heat applied in the annealing process may be minimized. Accordingly, the contact resistance of the element electrode layer 37 of the light emitting element core 30 of FIG. 12 may be reduced.

As described above, before performing the activation step, the second semiconductor material layer 320 may be pre-etched, so that in the activation step of activating the second conductivity type dopant, the exposed surface area of the second semiconductor material layer 320 may be increased. The Mg—H bonds of the second semiconductor material layer 320 may be easily decomposed in the activation step due to an increase in the exposed surface area of the second semiconductor material layer 320. Accordingly, in case that the second semiconductor material layer 320 is pre-etched, the Mg—H bonds are more easily decomposed compared to a case where the activation step is performed without pre-etching the second semiconductor material layer, so that hydrogen content in the second semiconductor material layer may be relatively reduced. Accordingly, the content of hydrogen in the second semiconductor layer 32 of the light emitting element core 30 according to the embodiment may be in a range about 1×10¹⁹/cm³ or less.

By the activation step, the Mg—H bonds may be decomposed sequentially from the surface of the second semiconductor material layer 320 of the third semiconductor structure 300 to the center thereof. Therefore, before performing the activation step, the second semiconductor material layer 320 may be pre-etched to activate the third semiconductor structures 300 spaced apart from each other, so that the Mg—H bonds may be decomposed from the surface of the second semiconductor material layer 320 of each of the third semiconductor structures 300 to the center thereof. Accordingly, the second semiconductor layer 32 of the light emitting element core 30 formed by activating the second semiconductor material layer 320 of the third semiconductor structure 300 may have a hydrogen content distribution in which the hydrogen content increases from the surface toward the center. For example, each of the light emitting element cores 30 may have a hydrogen content distribution in which the hydrogen content increases from the surface of the second semiconductor layer 32 toward the center thereof.

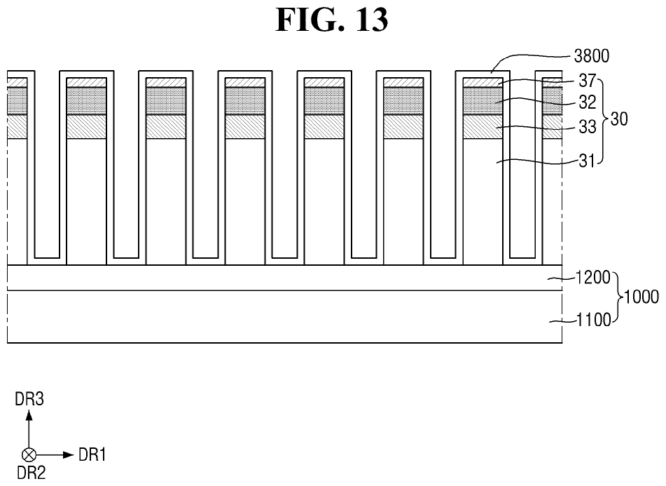

Referring to FIG. 13, an insulating material layer 3800 is formed on the light emitting element cores 30.

Specifically, the insulating material layer 3800 is formed on the outer surfaces of the light emitting element cores 30. The insulating material layer 3800 may be formed on the entire surface of the lower substrate 1000, and thus may be formed not only on the outer surface of the light emitting element core 30 but also on the top surface of the buffer material layer 1200 exposed by the light emitting element core 30. The outer surface of the light emitting element core 30 may include a side surface and a top surface of the light emitting element core 30. The insulating material layer 3800 may correspond to the element insulating film 38 of the light emitting element ED, and the insulating layer 3800 and the element insulating film 38 may include the same material.

The insulating material layer 3800 may be formed using a method of coating or immersing an insulating material on or in the outer surface of the light emitting element core 30. For example, the insulating material layer 3800 may be formed by atomic layer deposition (ALD) or chemical vapor deposition (CVD).

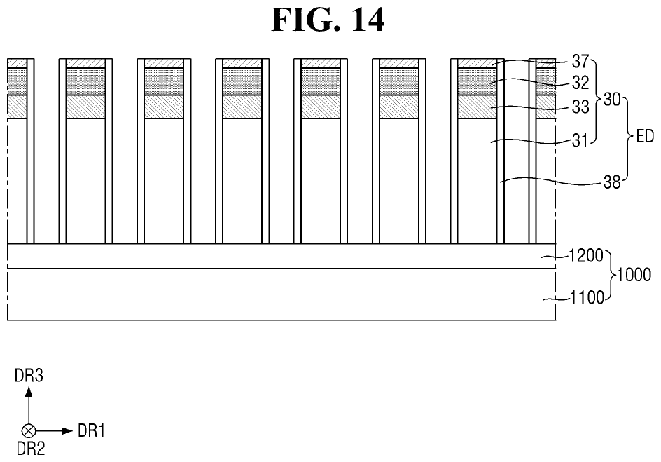

Next, referring to FIG. 14, the insulating material layer 3800 is partially removed to form the element insulating film 38 surrounding the side surface of the light emitting element core 30. The step of forming the element insulating film 38 may include an etching step of partially removing the insulating material layer 3800 such that an end surface of the light emitting element core 30, e.g., the top surface of the element electrode layer 37 is exposed. The step of partially removing the insulating material layer 3800 may be performed through a process such as etch-back or dry etching which is anisotropic etching.

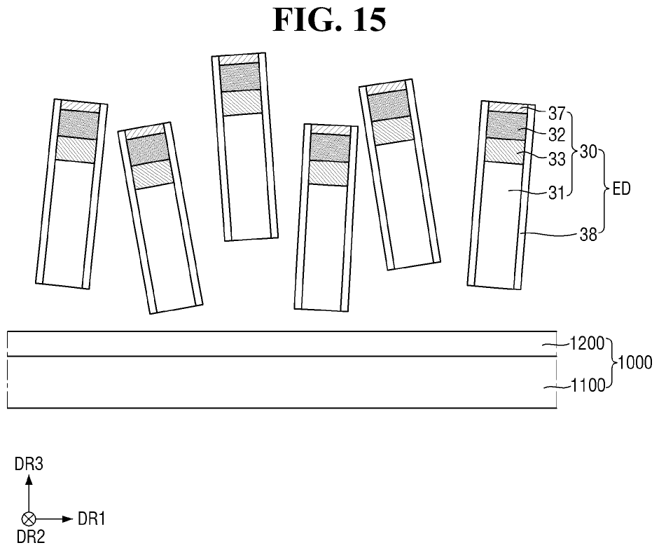

Next, referring to FIG. 15, the light emitting elements ED are separated from the lower substrate 1000. Specifically, the step of separating the light emitting elements ED from the lower substrate 1000 is not particularly limited. For example, the separation step of the light emitting elements ED may be performed by a physical separation method, a chemical separation method, or the like.

In the fabricating process of the light emitting element ED according to an embodiment, before activating the second conductivity type dopant doped into the second semiconductor layer, the second etching step may be performed to minimize the difference in Fermi level between the first semiconductor material layer and the second semiconductor material layer, thereby minimizing the difference in etching rate by the same etchant. Accordingly, the surface damage regions of the first semiconductor material layer and the second semiconductor material layer may be efficiently removed. Accordingly, it is possible to prevent a decrease in luminous efficiency of the light emitting element ED fabricated by the fabricating process according to the embodiment.

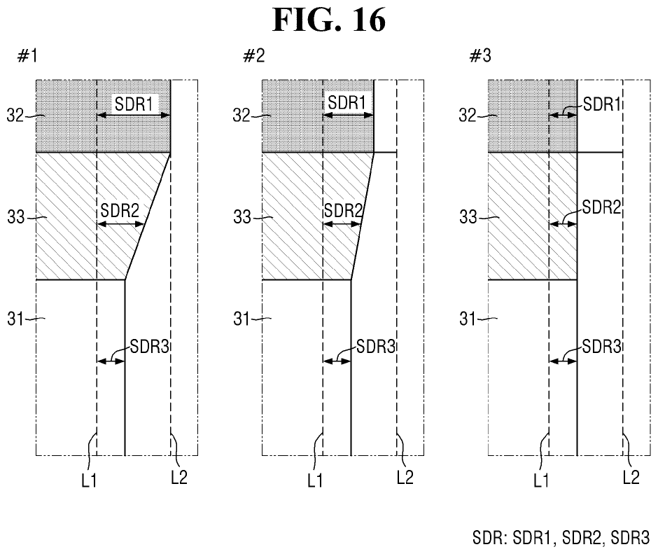

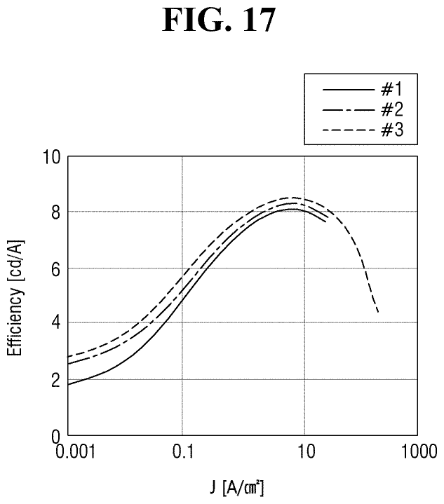

FIG. 16 is a schematic diagram schematically illustrating an area of a surface damage region of a second semiconductor layer of a light emitting element and a shape thereof according to over-etching. FIG. 17 is a graph illustrating the efficiency of the light emitting element shown in FIG. 16 according to over-etching of the light emitting element.

Referring to FIG. 16, a first reference line L1 and a second reference line L2 are illustrated. The first reference line L1 may refer to an inner reference line of the surface damage regions SDR3, SDR1, and SDR2 of the first semiconductor layer 31, the second semiconductor layer 32, and the light emitting layer 33 of the light emitting element ED. The second reference line L2 may refer to a reference line extending from the side surface of the second semiconductor layer 32 of the light emitting element ED of #1 in the extension direction of the light emitting element ED.

As illustrated in FIG. 16, the width of the surface damage region SDR3 of the first semiconductor layer 31 may be the same in the light emitting elements ED shown in #1, #2, and #3. However, the width of the surface damage region SDR1 of the second semiconductor layer 32 may be greater in the light emitting element ED shown in #1 than in the light emitting elements ED shown in #2 and #3, and may be greater in the light emitting element ED shown in #2 than in the light emitting element ED shown in #3. For example, the area of the surface damage region SDR of the light emitting element ED decreases from #1 to #3, and the second semiconductor layer 32 may be more over-etched from #1 to #3.

Referring to FIG. 17, FIG. 17 is a graph illustrating the efficiency of the light emitting element according to the over-etching of the light emitting element. As described above, as the second semiconductor layer 32 of the light emitting element ED is more over-etched from #1 to #3 in FIG. 16, it may be seen in FIG. 17 that the graph of #3 is above the graphs of #2 and #1. For example, it may be seen that as the second semiconductor layer 32 of the light emitting element ED is more over-etched, the efficiency of the light emitting element ED is increased.

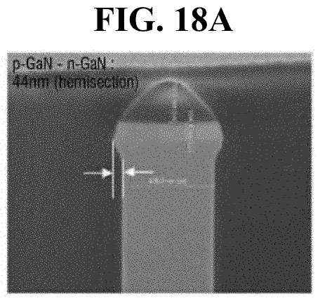

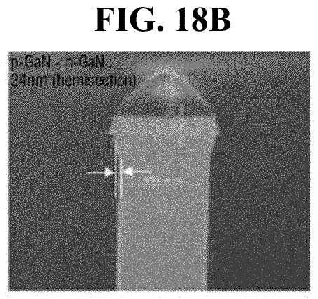

FIGS. 18A and 18B schematically illustrate examples of a light emitting element formed according to a fabricating process of the light emitting element.

FIG. 18A is a cross-sectional image of a light emitting element in which the second conductivity type dopant with which the second semiconductor layer is doped is activated before performing the second etching step, and the first and second etching steps are performed. FIG. 18B is a cross-sectional image of a light emitting element on which the first and second etching steps are performed before activating the second conductivity type dopant doped into the second semiconductor material layer, and then the second conductivity type dopant is activated.

As shown in FIGS. 18A and 18B, it may be seen that in the light emitting element of (a), the side surface of p-GaN protrudes more outward than the side surface of n-GaN by about 44 nm, and in the light emitting element of (b), the side surface of p-GaN protrudes more outward than the side surface of n-GaN by about 24 nm. For example, by performing the activation step of activating the second conductivity type dopant after the first and second etching steps, a difference in diameter between p-GaN and n-GaN may be reduced. Accordingly, surface damage that may be formed on the surface of p-GaN may be efficiently removed without remaining.

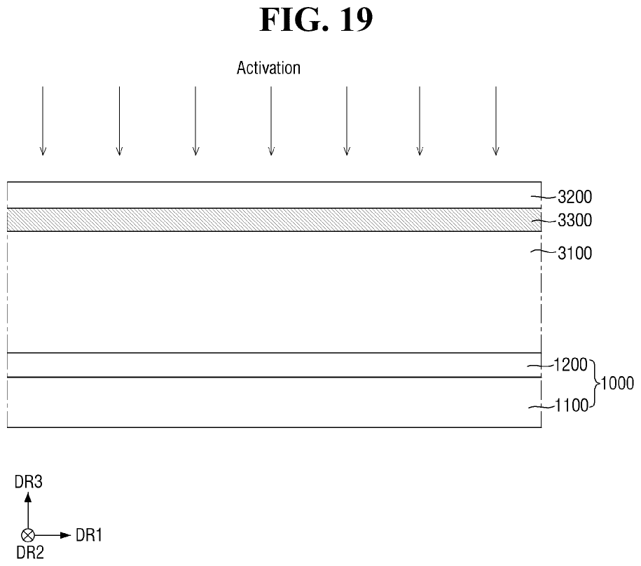

FIGS. 19 to 23 are schematic cross-sectional views of process steps illustrating a part of another example of a fabricating process of a light emitting element according to an embodiment.

Referring to FIG. 19, the semiconductor layers are formed on the lower substrate 1000, and a step of activating the second conductivity type dopant doped into the second semiconductor material layer 3200 is performed.

The semiconductor layers in which the first semiconductor material layer 3100, the light emitting material layer 3300, and the second semiconductor material layer 3200 are sequentially stacked are formed on the lower substrate 1000. As described above, the first semiconductor material layer 3100 and the light emitting material layer 3300 may correspond to the first semiconductor layer 31 and the light emitting layer 33 of the light emitting element ED, respectively. Accordingly, the first semiconductor material layer 3100 and the first semiconductor layer 31 may include the same material, and the light emitting material layer 3300 and the light emitting layer 33 may include the same material. For example, the first semiconductor material layer 3100 may be doped with the first conductivity type dopant, and the first conductivity type may be an n type. In an embodiment, the first semiconductor material layer 3100 may be n-GaN doped with n-type Si.

The second semiconductor material layer 3200 may correspond to the second semiconductor layer 32, but may be in a state in which the second conductivity type dopant has not been activated. Specifically, the second semiconductor material layer 3200 may be doped with the second conductivity type dopant, the second conductivity type may be a p type, and the second conductivity type dopant may be in a state bonded to hydrogen.

In an embodiment, the second semiconductor material layer 3200 may be p-GaN doped with p-type Mg, but Mg doped into the second semiconductor material layer 3200 may be in a non-activated state by combining with H. Unlike the fabricating process of the light emitting element ED according to the embodiment described above, in the embodiment, the doping amount of the second conductivity type dopant doped into the second semiconductor material layer 3200 may be in a range of about 1.0×10¹⁹/cm³ or less, but the disclosure is not limited thereto.

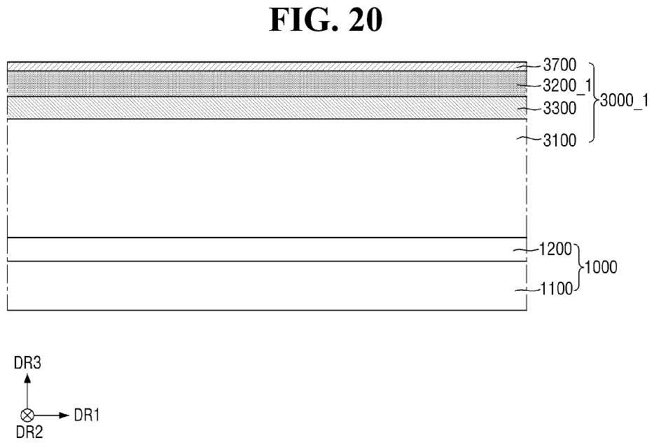

Next, referring to FIGS. 19 and 20, a step of activating the second conductivity type dopant doped into the second semiconductor material layer 3200 is performed.

Specifically, the step for activating the second conductivity type dopant doped into the second semiconductor material layer 3200 may include an annealing process in which heat treatment is performed within a predetermined temperature range. In the embodiment, the heat treatment of the annealing process may be performed in a temperature range of about 450° C. to about 750° C. By the activation step, the second semiconductor material layer 3200 of FIG. 19 may be activated to form, as shown in FIG. 20, an activated second semiconductor material layer 3200_1.

In the embodiment, before etching the semiconductor structure in which the semiconductor layers and the electrode material layer are stacked, the second conductivity type dopant doped into the second semiconductor material layer 3200 may be activated. However, as described above, in order to minimize a difference in Fermi level between the first semiconductor material layer and the second semiconductor material layer, the doping amount of the second conductivity type dopant doped into the second semiconductor material layer 3200 may be relatively smaller than that in the above-described example of the fabricating process of the light emitting element ED. Specifically, since the doping amount of the second conductivity type dopant doped into the second semiconductor material layer 3200 may be in a range of about 1.0×10¹⁹/cm³ or less, the concentration of holes included in the second semiconductor material layer may decrease, and in this case, the Fermi level of the second semiconductor material layer may increase (see the graph of FIG. 11).

Next, referring to FIG. 20, the electrode material layer 3700 is formed on the activated second semiconductor material layer 3200_1 to form a first semiconductor structure 3000_1.

Specifically, the electrode material layer 3700 is formed on the top surface of the second semiconductor material layer 32001, in which the second conductivity type dopant has been doped and activated, to form the first semiconductor structure 3000_1. The electrode material layer 3700 may be entirely formed on the top surface of the second semiconductor material layer 3200_1. As described above, the electrode material layer 3700 may correspond to the element electrode layer 37 of the light emitting element ED described above, and the electrode material layer 3700 and the element electrode layer 37 may include the same material.

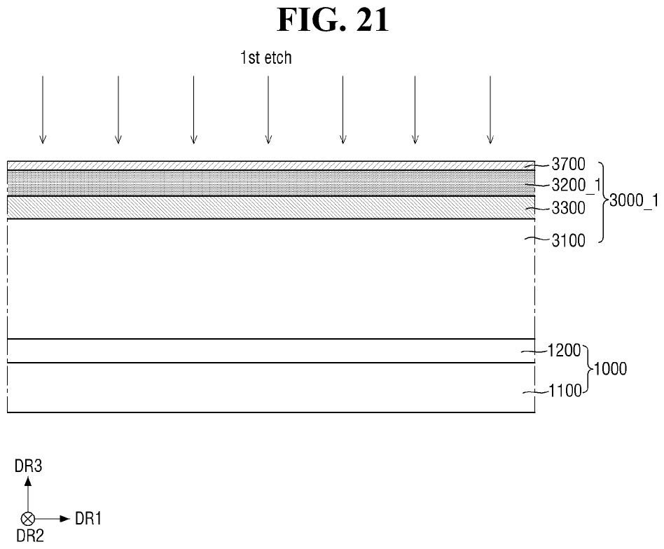

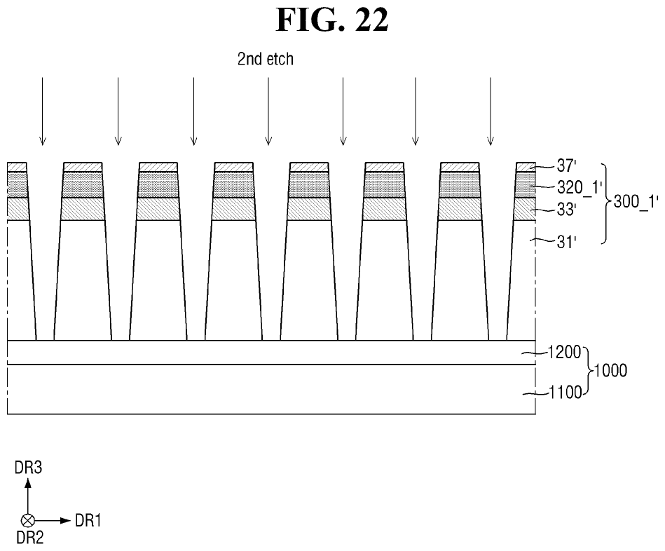

Subsequently, referring to FIGS. 21 and 22, the first semiconductor structure 3000_1 is etched to form second semiconductor structures 300′_1 spaced apart from each other (first etching step, 1^{st} etch).

Specifically, as shown in FIG. 21, the first etching step (1^{st} etch) of etching the first semiconductor structure 3000_1 in a direction, e.g., in the third direction DR3, perpendicular to the top surface of the lower substrate 1000 is performed to form, as shown in FIG. 22, the second semiconductor structures 300′_1 spaced apart from each other. The first etching step (1^{st} etch) of etching the first semiconductor structure 30001 may be performed by dry etching.

The second semiconductor material layer 3200_1 of the first semiconductor structure 3000_1 and a second semiconductor material layer 320_1′ of the second semiconductor structure 300′_1 may be p-GaN in which the second conductivity type dopant has been activated. The second semiconductor structure 300′_1, and the second semiconductor structure 300′ described above with reference to FIG. 7 may have substantially the same shape, but may be different from each other at least in that the second semiconductor material layer 320_1′ has been activated.

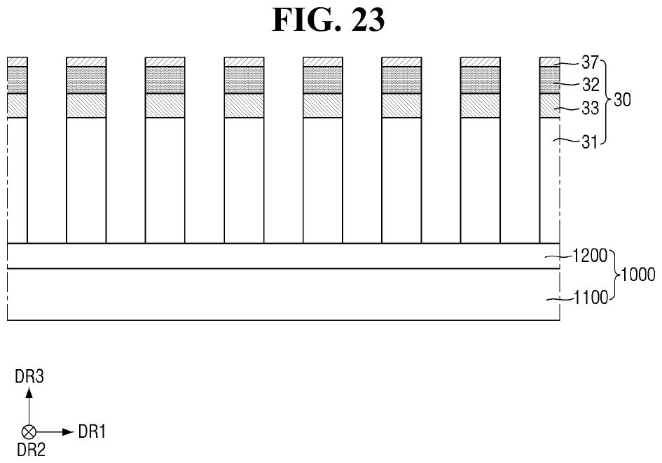

Next, referring to FIGS. 22 and 23, the second semiconductor structure 300′_1 is etched such that the side surfaces of the semiconductor layers included in the second semiconductor structure 300′_1 are aligned in a line to form the light emitting element cores 30 (second etching step, 2^{nd} etch).

Specifically, as shown in FIG. 22, the second etching step (2^{nd} etch) of etching the second semiconductor structures 300′_1 in the third direction DR3 is performed to form, as shown in FIG. 23, the light emitting element cores 30 whose side surfaces are perpendicular to the top surface of the lower substrate 1000. The second etching step (2^{nd} etch) of etching the second semiconductor structures 300′_1 may be performed by wet etching.

In the embodiment, the doping amount of the second conductivity type dopant doped into the second semiconductor material layer 320_1′ of the second semiconductor structure 300′_1 may be in a range of about 1.0×10¹⁹/cm³ or less, so that a difference in Fermi level between the second semiconductor material layer 320_1′ and the first semiconductor material layer 31′ may be minimized. Thus, the difference in etching rate between the second semiconductor material layer 320_1′ and the first semiconductor material layer 31′ with respect to an etchant used in the second etching step (2^{nd} etch) may be minimized, so that surface damage occurred on the surface of the second semiconductor structure 300′_1 by the first etching step (1^{st} etch) may be removed by the etchant. Accordingly, the doping amount of the second conductivity type dopant doped into the second semiconductor material layer may be adjusted to minimize the difference in Fermi level between the first semiconductor material layer and the second semiconductor material layer, thereby minimizing the difference in etching rate by the same etchant. Accordingly, the surface damage regions of the first semiconductor material layer and the second semiconductor material layer may be efficiently removed. Accordingly, it is possible to prevent a decrease in luminous efficiency of the light emitting element ED fabricated by the fabricating process according to the embodiment.

Next, referring to FIGS. 12 to 14, the insulating material layer 3800 is stacked on the light emitting element core 30, and a part of the insulating material layer 3800 is removed to form the light emitting elements ED.

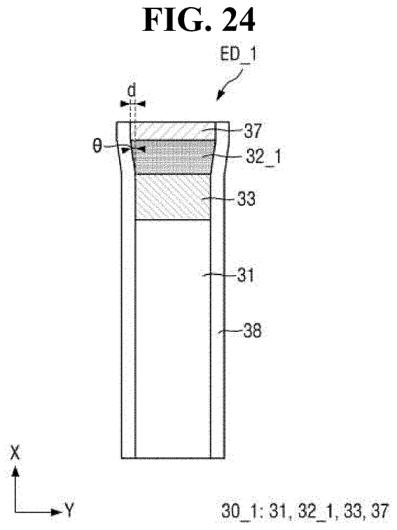

FIG. 24 is a schematic cross-sectional view of a light emitting element according to another embodiment.

Referring to FIG. 24, a light emitting element ED_1 according to an embodiment is different from the light emitting element ED of FIG. 2 in that the cross-sectional structure of a second semiconductor layer 32_1 has a trapezoidal shape.

Specifically, a light emitting element core 30_1 of the light emitting element ED_1 according to the embodiment may include the first semiconductor layer 31, the second semiconductor layer 321, the light emitting layer 33, and the element electrode layer 37. In the embodiment, the side surface of the second semiconductor layer 32_1 may protrude more outward than the side surface of the first semiconductor layer 31 by a predetermined distance d. For example, the diameter of the second semiconductor layer 32_1 may be greater than the diameter of the first semiconductor layer 31. The diameter of the second semiconductor layer 32_1 may be greater than the diameter of the first semiconductor layer 31 by twice (d×2) the predetermined distance.

This may be formed by a difference in etching rate between the first semiconductor layer 31 and the second semiconductor layer 32_1 with respect to the same etchant used in the second etching step (2^{nd} etch) performed by wet etching during the fabricating process of the light emitting element ED_1. In the cross-sectional view of the light emitting element ED_1 taken in its longitudinal direction X, an angle θ formed by the side surface of the second semiconductor layer 32_1 may be in a range of 20° or less, but the disclosure is not limited thereto.

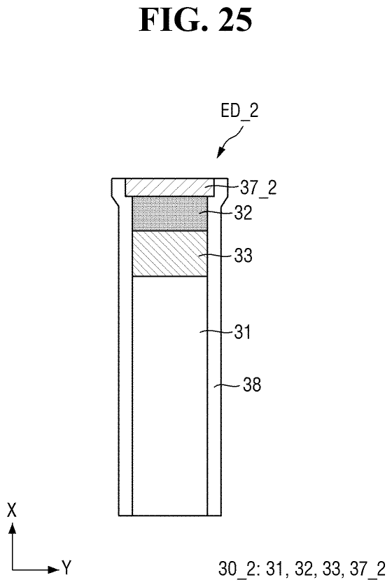

FIG. 25 is a schematic cross-sectional view of a light emitting element according to still another embodiment.

Referring to FIG. 25, a light emitting element ED_2 is different from the light emitting element ED shown in FIG. 2 in that the side surface of an element electrode layer 37_2 protrudes more outward than the side surface of the second semiconductor layer 32.

Specifically, a light emitting element core 30_2 of the light emitting element ED_2 according to the embodiment may include the first semiconductor layer 31, the second semiconductor layer 32, the light emitting layer 33, and the element electrode layer 37_2. In this embodiment, the side surface of the element electrode layer 37_2 may protrude more outward than the side surface of the second semiconductor layer 32. This may be formed by a difference in etching rate between the element electrode layer 37_2 and the second semiconductor layer 32 with respect to the same etchant used in the second etching step (2^{nd} etch) performed by wet etching during the fabricating process of the light emitting element ED_2.

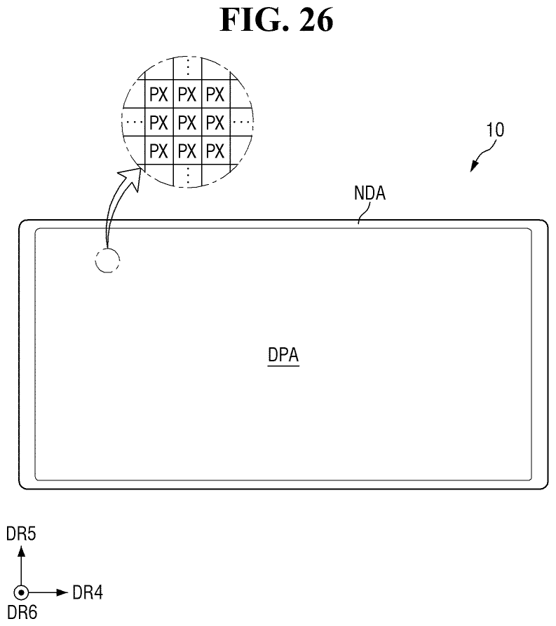

FIG. 26 is a schematic plan view of a display device according to an embodiment.

Referring to FIG. 26, a display device 10 displays a moving image or a still image. The display device 10 may refer to any electronic device providing a display screen. Examples of the display device 10 may include a television, a laptop computer, a monitor, a billboard, an Internet-of-Things device, a mobile phone, a smartphone, a tablet personal computer (PC), an electronic watch, a smartwatch, a watch phone, a head-mounted display, a mobile communication terminal, an electronic notebook, an electronic book, a portable multimedia player (PMP), a navigation device, a game machine, a digital camera, a camcorder, and the like, which provide a display screen.

The display device 10 includes a display panel which provides a display screen. Examples of the display panel may include an inorganic light emitting diode display panel, an organic light emitting display panel, a quantum dot light emitting display panel, a plasma display panel, and a field emission display panel. Hereinafter, as an example of the display panel, a case in which the above-described light emitting element ED, specifically, an inorganic light emitting diode display panel is applied will be exemplified, but the disclosure is not limited thereto. Other display panels may also be applied as long as the same technical spirit is applicable thereto.

Hereinafter, a fourth direction DR4, a fifth direction DR5, and a sixth direction DR6 are defined in drawings of an embodiment describing the display device 10. The fourth direction DR4 and the fifth direction DR5 may be directions perpendicular to each other in a plane. The sixth direction DR6 may be a direction perpendicular to a plane on which the fourth direction DR4 and the fifth direction DR5 are located. The sixth direction DR6 is perpendicular to each of the fourth direction DR4 and the fifth direction DR5. In the embodiment describing the display device 10, the sixth direction DR6 indicates a thickness direction of the display device 10.

The display device 10 may have a rectangular shape including long and short sides such that the side in the fourth direction DR4 is longer than the side in the fifth direction DR5 in a plan view. A corner portion where the long side and the short side of the display device 10 meet may be right-angled in a plan view. However, the disclosure is not limited thereto, and it may be rounded to have a curved shape. The planar shape of the display device 10 is not limited to the illustrated example, and may be other shapes such as a square shape, a quadrilateral shape with rounded corners (vertices), other polygonal shapes, and a circular shape.

A display surface of the display device 10 may be disposed on a side of the sixth direction DR6 which is the thickness direction. In embodiments describing the display device 10, unless otherwise noted, the term “upward” refers to a side of the sixth direction DR6, which is the display direction, and the term “top surface” refers to a surface toward the side of the sixth direction DR6. Further, the term “downward” refers to the other side of the sixth direction DR6, which is an opposite direction to the display direction, and the term “bottom surface” refers to a surface toward the other side of the sixth direction DR6. Furthermore, “left,” “right,” “upper,” and “lower” indicate directions when the display device 10 is viewed from above. For example, “right side” indicates a side of the fourth direction DR4, “left side” indicates the other side of the fourth direction DR4, “upper side” indicates a side of the fifth direction DR5, and “lower side” indicates the other side of the fifth direction DR5.

The display device 10 may include a display area DPA and a non-display area NDA. The display area DPA is an area where an image can be displayed, and the non-display area NDA is an area where an image is not displayed.

The shape of the display area DPA may follow the shape of the display device 10. For example, the shape of the display area DPA may have a rectangular shape similar to the overall shape of the display device 10 in a plan view. The display area DPA may substantially occupy the center of the display device 10.

The display area DPA may include pixels PX. The pixels PX may be arranged in a matrix. The shape of each pixel PX may be a rectangular or square shape in a plan view. However, the shape of each pixel PX is not limited thereto, and may be a rhombic shape in which each side is inclined with respect to a direction. The pixels PX may be alternately disposed in a stripe type or a PenTile® type.

The non-display area NDA may be disposed around the display area DPA. The non-display area NDA may completely or partially surround the display area DPA. In an embodiment, the display area DPA may have a rectangular shape, and the non-display area NDA may be disposed adjacent to four sides of the display area DPA. The non-display area NDA may form a bezel of the display device 10. In the non-display area NDA, wires, circuit drivers, or pad portions on which an external device is mounted may be disposed in the display device 10.

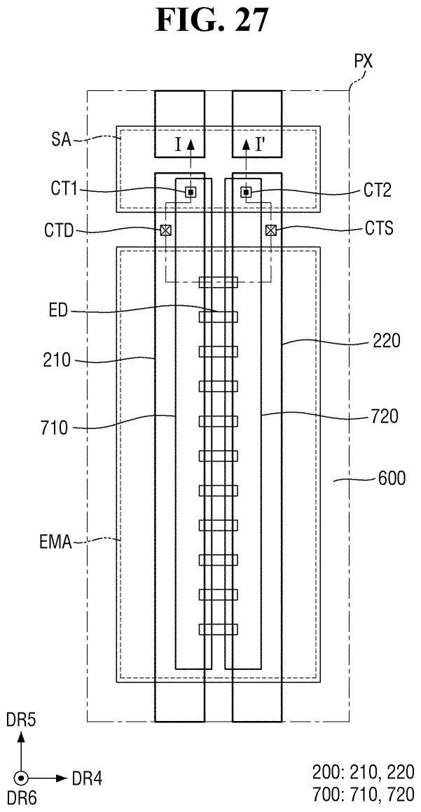

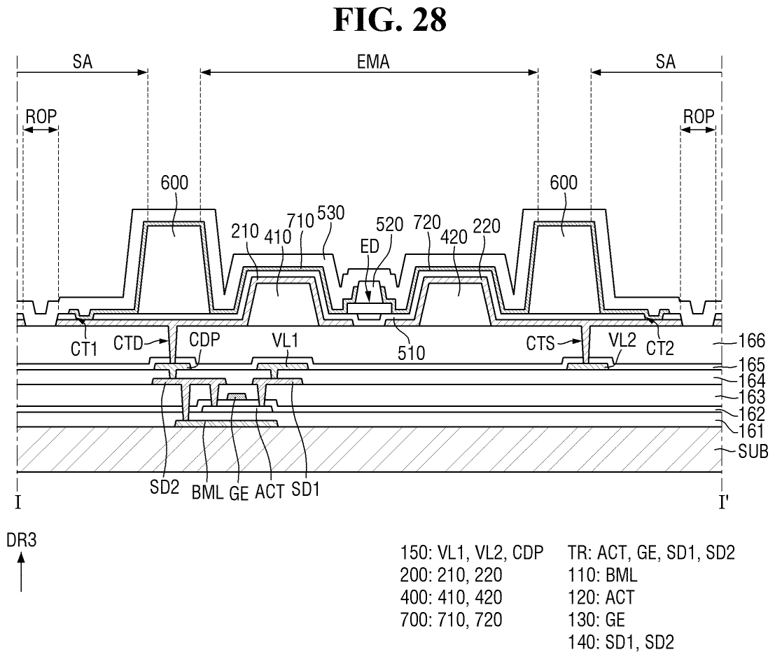

FIG. 27 is a schematic plan layout view illustrating a pixel of a display device according to an embodiment. FIG. 28 is a schematic cross-sectional view illustrating an example taken along line I-I′ of FIG. 27.

Referring to FIG. 27, each pixel PX of the display device 10 may include an emission area EMA and a non-emission area. The emission area EMA may be defined as an area from which light emitted from a light emitting element ED is emitted, and the non-emission area may be defined as an area from which light is not emitted because the light emitted from the light emitting element ED does not reach this area.

The emission area EMA may include an area in which the light emitting element ED is disposed and an area adjacent thereto. The emission area EMA may further include a region in which the light emitted from the light emitting element ED is reflected or refracted by another member and emitted.

Each pixel PX may further include a sub-region SA disposed in the non-emission area. The light emitting element ED may not be provided in the sub-region SA. The sub-region SA may be disposed above the emission area EMA in a pixel PX in a plan view. The sub-region SA may be disposed between the emission areas EMA of the pixels PX disposed adjacent to each other in the fifth direction DR5. The sub-region SA may include a region in which an electrode layer 200 and a contact electrode 700 are electrically connected to each other through contact portions CT1 and CT2.

The sub-region SA may include a separation portion ROP. The separation portion ROP of the sub-region SA may be the region where first electrodes 210 and second electrodes 220 of the electrode layers 200 included in different pixels PX adjacent to each other in the fifth direction DR5 are separated from each other.

Referring to FIGS. 27 and 28, the display device 10 may include a substrate SUB, a circuit element layer disposed on the substrate SUB, and a light emitting element layer disposed on the circuit element layer.

The substrate SUB may be an insulating substrate. The substrate SUB may be made of an insulating material such as glass, quartz, or polymer resin. Further, the substrate SUB may be a rigid substrate, but may also be a flexible substrate which can be bent, folded, or rolled.

The circuit element layer may be disposed on the substrate SUB. The circuit element layer may include a lower metal layer 110, a semiconductor layer 120, a first conductive layer 130, a second conductive layer 140, a third conductive layer 150, and insulating layers.

The lower metal layer 110 is disposed on the substrate SUB. The lower metal layer 110 may include a light blocking pattern BML. The light blocking pattern BML may be disposed to cover (or overlap) at least a channel region of an active layer ACT of a transistor TR from the bottom. However, the disclosure is not limited thereto, and the light blocking pattern BML may be omitted.

The lower metal layer 110 may contain a material that blocks light. For example, the lower metal layer 110 may be made of an opaque metal material that blocks transmission of light.

A buffer layer 161 may be disposed on the lower metal layer 110. The buffer layer 161 may be disposed to cover the entire surface of the substrate SUB where the lower metal layer 110 is disposed. The buffer layer 161 may serve to protect transistors from moisture permeating through the substrate SUB that is susceptible to moisture permeation.

The semiconductor layer 120 is disposed on the buffer layer 161. The semiconductor layer 120 may include the active layer ACT of the transistor TR. The active layer ACT of the transistor TR may be disposed to overlap the light blocking pattern BML of the lower metal layer 110 as described above.

The semiconductor layer 120 may include polycrystalline silicon, monocrystalline silicon, an oxide semiconductor, or the like. In an embodiment, in case that the semiconductor layer 120 contains polycrystalline silicon, the polycrystalline silicon may be formed by crystallizing amorphous silicon. In case that the semiconductor layer 120 contains polycrystalline silicon, the active layer ACT of the transistor TR may include doping regions doped with impurities and channel regions disposed therebetween. In an embodiment, the semiconductor layer 120 may contain an oxide semiconductor. The oxide semiconductor may be, for example, indium tin oxide (ITO), indium zinc oxide (IZO), indium gallium oxide (IGO), indium zinc tin oxide (IZTO), indium gallium zinc oxide (IGZO), indium gallium tin oxide (IGTO), indium gallium zinc tin oxide (IGZTO) or the like.

A gate insulating layer 162 may be disposed on the semiconductor layer 120. The gate insulating layer 162 may function as a gate insulating layer of the transistor TR. The gate insulating layer 162 may be formed as a multilayer in which inorganic layers including an inorganic material, for example, at least one of silicon oxide (SiOₓ), silicon nitride (SiNₓ) and silicon oxynitride (SiOₓN_{y}) are alternately stacked.

The first conductive layer 130 may be disposed on the gate insulating layer 162. The first conductive layer 130 may include a gate electrode GE of the transistor TR. The gate electrode GE may be disposed to overlap the channel region of the active layer ACT in the sixth direction DR6 which is the thickness direction of the substrate SUB.

A first interlayer insulating layer 163 may be disposed on the first conductive layer 130. The first interlayer insulating layer 163 may be disposed to cover the gate electrode GE. The first interlayer insulating layer 163 may function as an insulating layer between the first conductive layer 130 and other layers disposed thereon to protect the first conductive layer 130.

A second conductive layer 140 may be disposed on the first interlayer insulating layer 163. The second conductive layer 140 may include a drain electrode SD1 of the transistor TR and a source electrode SD2 of the transistor TR.

The drain electrode SD1 and the source electrode SD2 of the transistor TR may be electrically connected to both ends of the active layer ACT of the transistor TR through contact holes penetrating the first interlayer insulating layer 163 and the gate insulating layer 162. Further, the source electrode SD2 of the transistor TR may be electrically connected to the light blocking pattern BMIL of the lower metal layer 110 through another contact hole penetrating the first interlayer insulating layer 163, the gate insulating layer 162, and the buffer layer 161.

A second interlayer insulating layer 164 may be disposed on the second conductive layer 140. The second interlayer insulating layer 164 may be disposed to cover the drain electrode SD1 of the transistor TR and the source electrode SD2 of the transistor TR. The second interlayer insulating layer 164 may function as an insulating layer between the second conductive layer 140 and other layers disposed thereon, and may protect the second conductive layer 140.

A third conductive layer 150 may be disposed on the second interlayer insulating layer 164. The third conductive layer 150 may include a first voltage line VL1, a second voltage line VL2, and a conductive pattern CDP.

The first voltage line VL1 may overlap at least a part of the drain electrode SD1 of the transistor TR in the thickness direction of the substrate SUB. A high-potential voltage (or a first source voltage) supplied to the transistor TR may be applied to the first voltage line VL1.

The second voltage line VL2 may be electrically connected to the second electrode 220 through a second electrode contact hole CTS penetrating a via layer 166 and a passivation layer 165 to be described below. A low-potential voltage (or a second source voltage) lower than the high-potential voltage supplied to the first voltage line VL1 may be applied to the second voltage line VL2. For example, the high-potential voltage (or the first source voltage) supplied to the transistor TR may be applied to the first voltage line VL1, and the low-potential voltage (or the second source voltage) lower than the high-potential voltage supplied to the first voltage line VL1 may be applied to the second voltage line VL2.

The conductive pattern CDP may be electrically connected to the source electrode SD2 of the transistor TR. The conductive pattern CDP may be electrically connected to the source electrode SD2 of the transistor TR through the contact hole penetrating the second interlayer insulating layer 164. Further, the conductive pattern CDP may be electrically connected to the first electrode 210 through a first electrode contact hole CTD penetrating the via layer 166 and the passivation layer 165 to be described below. The transistor TR may transmit the first source voltage applied from the first voltage line VL1 to the first electrode 210 through the conductive pattern CDP.

The passivation layer 165 may be disposed on the third conductive layer 150. The passivation layer 165 may be disposed to cover the third conductive layer 150. The passivation layer 165 may serve to protect the third conductive layer 150.

Each of the buffer layer 161, the gate insulating layer 162, the first interlayer insulating layer 163, the second interlayer insulating layer 164, and the passivation layer 165 described above may be formed of inorganic layers stacked in an alternating manner. For example, the buffer layer 161, the gate insulating layer 162, the first interlayer insulating layer 163, the second interlayer insulating layer 164, and the passivation layer 165 described above may be formed as a double layer formed by stacking, or a multiplayer formed by alternately stacking, inorganic layers including at least one of silicon oxide (SiOₓ), silicon nitride (SiNₓ), or silicon oxynitride (SiOₓN_{y}). However, the disclosure is not limited thereto, and the buffer layer 161, the gate insulating layer 162, the first interlayer insulating layer 163, the second interlayer insulating layer 164, and the passivation layer 165 described above may be formed as a single inorganic layer containing the above-described insulating material.

The via layer 166 may be disposed on the passivation layer 165. The via layer 166 may include an organic insulating material, for example, an organic material such as polyimide (PI). The via layer 166 may function to flatten a surface. Therefore, the top surface (or the surface) of the via layer 166 on which the light emitting element layer to be described below is disposed may have a substantially flat surface regardless of the shape or existence of the pattern disposed therebelow.

The light emitting element layer may be disposed on the circuit element layer. The light emitting element layer may be disposed on the via layer 166. The light emitting element layer may include a first bank 400, the electrode layer 200, a first insulating layer 510, a second bank 600, the light emitting elements ED, and the contact electrode 700.

The first bank 400 may be disposed on the via layer 166 in the emission area EMA. The first bank 400 may be disposed directly on a surface of the via layer 166. The first bank 400 may have a structure in which at least a part of the first bank 400 protrudes upward (e.g., a side in the sixth direction DR6) with respect to a surface of the via layer 166. The protruding part of the first bank 400 may have an inclined side surface. The first bank 400 may serve to change the traveling direction of the light emitted from the light emitting element ED toward the inclined side surface of the first bank 400 to an upward direction (e.g., a display direction).

The first bank 400 may include a first sub-bank 410 and a second sub-bank 420 spaced apart from each other. The first sub-bank 410 and the second sub-bank 420 spaced apart from each other may serve as a partition wall that provides a space where the light emitting element ED is disposed and also changes the traveling direction of the light emitted from the light emitting element ED to the display direction.

Although it is illustrated in the drawing that the side surface of the first bank 400 is include in a linear shape, the disclosure is not limited thereto. However, the disclosure is not limited thereto. For example, the side surface (or outer surface) of the first bank 400 may have a curved semicircular or semielliptical shape. In an embodiment, the first bank 400 may include an organic insulating material such as polyimide (PI), but the disclosure is not limited thereto.

The electrode layer 200 may extend in a direction and may be disposed across the emission area EMA and the sub-region SA. The electrode layer 200 may transmit an electrical signal applied from a circuit element layer to the light emitting element ED so that the light emitting element ED emits light. Further, the electrode layer 200 may also be used for generating an electric field used in the process of aligning the light emitting elements ED.

The electrode layer 200 may be disposed on the first bank 400 and the via layer 166 exposed by the first bank 400. In the emission area EMA, the electrode layer 200 may be disposed on the first bank 400, and in the non-emission area, the electrode layer 200 may be disposed on the via layer 166 exposed by the first bank 400.

The electrode layer 200 may include the first electrode 210 and the second electrode 220. The first electrode 210 and the second electrode 220 may be spaced apart from each other.

The first electrode 210 may be located on a left side of each pixel PX in a plan view. The first electrode 210 may extend in the fifth direction DR5 in a plan view. The first electrode 210 may be disposed across the emission area EMA and the sub-region SA. The first electrode 210 may extend in the fifth direction DR5 in a plan view and may be separated from the first electrode 210 of another pixel PX adjacent thereto in the fifth direction DR5 at the separation portion ROP of the sub-region SA.

The second electrode 220 may be separated from the first electrode 210 in the fourth direction DR4. The second electrode 220 may be located on a right side of each pixel PX in a plan view. The second electrode 220 may extend in the fifth direction DR5 in a plan view. The second electrode 220 may be disposed across the emission area EMA and the sub-region SA. The second electrode 220 may extend in the fifth direction DR5 in a plan view and may be separated from the second electrode 220 of another pixel PX adjacent thereto in the fifth direction DR5 at the separation portion ROP of the sub-region SA.

Specifically, the first electrode 210 may be disposed on the first sub-bank 410, and the second electrode 220 may be disposed on the second sub-bank 420 in the emission area EMA. The first electrode 210 may extend outward from the first sub-bank 410 and may also be disposed on the via layer 166 exposed by the first sub-bank 410. Similarly, the second electrode 220 may extend outward from the second sub-bank 420 and may also be disposed on the via layer 166 exposed by the second sub-bank 420. The first electrode 210 and the second electrode 220 may be spaced apart from each other and face each other in a separation region between the first sub-bank 410 and the second sub-bank 420. The via layer 166 may be exposed in a region where the first electrode 210 and the second electrode 220 face each other while being spaced apart from each other.

The first electrode 210 may be spaced apart from a first electrode 210 of another pixel PX adjacent in the fifth direction DR5 with the separation portion ROP interposed therebetween in the sub-region SA. Similarly, the second electrode 220 may be spaced apart from a second electrode 220 of another pixel PX adjacent in the fifth direction DR5 with the separation portion ROP interposed therebetween in the sub-region SA. Accordingly, the first electrode 210 and the second electrode 220 may expose the via layer 166 in the separation portion ROP of the sub-region SA.

The first electrode 210 may be electrically connected to the conductive pattern CDP of the circuit element layer through the first electrode contact hole CTD penetrating the via layer 166 and the passivation layer 165. Specifically, the first electrode 210 may contact the top surface of the conductive pattern CDP exposed by the first electrode contact hole CTD. The first source voltage applied from the first voltage line VL1 may be transmitted to the first electrode 210 through the conductive pattern CDP.

The second electrode 220 may be electrically connected to the second voltage line VL2 of the circuit element layer through the second electrode contact hole CTS penetrating the via layer 166 and the passivation layer 165. Specifically, the second electrode 220 may contact the top surface of the second voltage line VL2 exposed by the second electrode contact hole CTS. The second source voltage applied from the second voltage line VL2 may be transmitted to the second electrode 220.

The electrode layer 200 may include a conductive material having high reflectivity. For example, the electrode layer 200 may include a metal such as silver (Ag), copper (Cu), or aluminum (Al) as a material having high reflectivity, or may include an alloy including aluminum (Al), nickel (Ni), lanthanum (La), and the like. The electrode layer 200 may reflect the light emitted from the light emitting element ED and traveling toward the side surface of the first bank 400 in the upward direction of each pixel PX.

However, the disclosure is not limited thereto, and the electrode layer 200 may further include a transparent conductive material. For example, the electrode layer 200 may include a material such as ITO, IZO, and ITZO. In some embodiments, the electrode layer 200 may have a structure in which at least one transparent conductive material and at least one metal layer having high reflectivity are stacked, or may be formed as a layer including them. For example, the electrode layer 200 may have a stacked structure of ITO/Ag/ITO, ITO/Ag/IZO, ITO/Ag/ITZO/IZO, or the like.

The first insulating layer 510 may be disposed on the via layer 166 on which the electrode layer 200 is formed. The first insulating layer 510 may insulate the first electrode 210 and the second electrode 220 from each other while protecting the electrode layer 200.

The first insulating layer 510 may include an inorganic insulating material. For example, the first insulating layer 510 may include at least one of inorganic insulating materials such as silicon oxide (SiOₓ), silicon nitride (SiNₓ), silicon oxynitride (SiOₓN_{y}), aluminum oxide (AlₓO_{y}), aluminum nitride (AlN), and the like. The first insulating layer 510 made of an inorganic material may have a surface shape reflecting the pattern shape of the electrode layer 200 disposed thereunder. For example, the first insulating layer 510 may have a stepped structure having step differences or height differences according to the shape of the electrode layer 200 disposed under the first insulating layer 510. Specifically, the first insulating layer 510 may include a stepped structure in which its top surface is partially recessed in a region where the first electrode 210 and the second electrode 220 face each other while being spaced apart from each other. Accordingly, the top surface of the first insulating layer 510 disposed on the first electrode 210 and the second electrode 220 may be at a height higher than the height of the top surface of the first insulating layer 510 disposed on the via layer 166 on which the first electrode 210 and the second electrode 220 are not disposed. In the disclosure, a height of a top surface of an arbitrary layer may be relatively compared based on a height measured from a flat reference surface (e.g., the top surface of the via layer 166) that does not have a lower stepped structure.

The first insulating layer 510 may include a first contact portion (or contact hole) CT1 exposing a part of the top surface of the first electrode 210 in the sub-region SA and a second contact portion CT2 exposing a part of the top surface of the second electrode 220 in the sub-region SA. The first electrode 210 may be electrically connected to a first contact electrode 710 to be described below through the first contact portion CT1 penetrating the first insulating layer 510 in the sub-region SA, and the second electrode 220 may be electrically connected to a second contact electrode 720 to be described below through the second contact portion CT2 penetrating the first insulating layer 510 in the sub-region SA.

The second bank 600 may be disposed on the first insulating layer 510. The second bank 600 may be disposed in the form of a grid pattern including portions extending in the fourth and fifth directions DR4 and DR5 in a plan view.

The second bank 600 may be disposed across the boundary of adjacent pixels PX to divide the pixels PX and may divide the emission area EMA and the sub-region SA. Further, the second bank 600 is formed to have a height greater than that of the first bank 400. Accordingly, in an inkjet printing step for aligning the light emitting elements ED during the fabricating process of the display device 10, ink in which the light emitting elements ED are dispersed can be sprayed into the emission area EMA without being mixed with an adjacent pixel PX.

The light emitting elements ED may be arranged in the emission area EMA. The light emitting elements ED may not be disposed in the sub-region SA.

The light emitting elements ED may be disposed on the first insulating layer 510 between the first sub-bank 410 and the second sub-bank 420. The light emitting elements ED may be disposed on the first insulating layer 510 between the first electrode 210 and the second electrode 220.

The light emitting element ED may extend in a direction, and both ends of the light emitting element ED may be disposed above the first electrode 210 and the second electrode 220, respectively. For example, the light emitting elements ED may be disposed such that one end (or first end) thereof is placed on the first electrode 210 and the other end (or second end) thereof is placed on the second electrode 220.

The length of each light emitting element ED (for example, the length of the light emitting element ED in the fourth direction DR4 in the drawing) may be smaller than the shortest distance between the first sub-bank 410 and the second sub-bank 420 spaced apart from each other in the fourth direction DR4. The length of each light emitting element ED may be greater than the shortest distance between the first electrode 210 and the second electrode 220 spaced apart in the fourth direction DR4. A distance in the fourth direction DR4 between the first sub-bank 410 and the second sub-bank 420 may be formed to be greater than the length of each light emitting element ED, and the distance in the fourth direction DR4 between the first electrode 210 and the second electrode 220 may be formed to be smaller than the length of each light emitting element ED, so that the light emitting elements ED may be disposed such that both ends thereof are placed above the first electrode 210 and the second electrode 220, respectively, between the first sub-bank 410 and the second sub-bank 420.

The light emitting elements ED may be arranged to be spaced apart from each other in the fifth direction DR5 in which the first electrode 210 and the second electrode 220 extend, and may be aligned with each other substantially parallel to each other.

The second insulating layer 520 may be disposed on the light emitting element ED. The second insulating layer 520 may be partially disposed on the light emitting element ED so as to expose both ends of the light emitting element ED. The second insulating layer 520 may be disposed to partially cover the outer surface of the light emitting element ED without covering (or overlapping) one end and the other end of the light emitting element ED.

The portion of the second insulating layer 520 disposed on the light emitting element ED may be arranged on the first insulating layer 510 to extend in the fifth direction DR5 in a plan view, so that it may form a linear or island-like pattern in each pixel PX. The second insulating layer 520 may protect the light emitting element ED while fixing the light emitting element ED during the fabricating process of the display device 10. The second insulating layer 520 may be disposed to fill a space between the light emitting element ED and the first insulating layer 510 disposed therebelow.

The contact electrode 700 may be disposed on the second insulating layer 520. The contact electrode 700 may be disposed on the first insulating layer 510 on which the light emitting element ED is disposed. The contact electrode 700 may include the first contact electrode 710 and the second contact electrode 720 spaced apart from each other.

The first contact electrode 710 may be disposed on the first electrode 210 in the emission area EMA. The first contact electrode 710 may extend in the fifth direction DR5 above the first electrode 210. The first contact electrode 710 may contact the first electrode 210 and one end of the light emitting element ED.

The first contact electrode 710 may contact the first electrode 210 exposed by the first contact portion CT1 penetrating the first insulating layer 510 in the sub-region SA, and may contact one end of the light emitting element ED in the emission area EMA. For example, the first contact electrode 710 may serve to electrically connect the first electrode 210 to one end of the light emitting element ED.

The second contact electrode 720 may be disposed on the second electrode 220 in the emission area EMA. The second contact electrode 720 may extend in the fifth direction DR5 above the second electrode 220. The second contact electrode 720 may contact the second electrode 220 and the other end of the light emitting element ED.

The second contact electrode 720 may contact the second electrode 220 exposed by the second contact portion CT2 penetrating the first insulating layer 510 in the sub-region SA, and may contact the other end of the light emitting element ED in the emission area EMA. For example, the second contact electrode 720 may serve to electrically connect the second electrode 220 to the second end of the light emitting element ED.

The first contact electrode 710 and the second contact electrode 720 may be spaced apart from each other on the light emitting element ED. Specifically, the first contact electrode 710 and the second contact electrode 720 may be spaced apart from each other with the second insulating layer 520 interposed therebetween. The first contact electrode 710 and the second contact electrode 720 may be electrically insulated from each other.

The first contact electrode 710 and the second contact electrode 720 may include the same material. For example, each of the first contact electrode 710 and the second contact electrode 720 may include a conductive material. For example, the first contact electrode 710 and the second contact electrode 720 may include ITO, IZO, ITZO, aluminum (Al), or the. As an example, each of the first contact electrode 710 and the second contact electrode 720 may include a transparent conductive material. Since each of the first contact electrode 710 and the second contact electrode 720 includes a transparent conductive material, light emitted from the light emitting element ED may pass through the first contact electrode 710 and the second contact electrode 720 to travel toward the first electrode 210 and the second electrode 220, and may be reflected from the surfaces of the first electrode 210 and the second electrode 220.

The first contact electrode 710 and the second contact electrode 720 may include the same material and may be formed of the same layer. The first contact electrode 710 and the second contact electrode 720 may be simultaneously formed by a same step.

The third insulating layer 530 may be disposed on the contact electrode 700. The third insulating layer 530 may cover the light emitting element layer disposed thereunder. The third insulating layer 530 may cover the first bank 400, the electrode layer 200, the first insulating layer 510, the light emitting elements ED, and the contact electrode 700. The third insulating layer 530 may be disposed above the second bank 600 to also cover the second bank 600.

The third insulating layer 530 may serve to protect the light emitting element layer disposed thereunder from foreign substances such as dust particles, moisture, or oxygen. The third insulating layer 530 may serve to protect the first bank 400, the electrode layer 200, the first insulating layer 510, the light emitting elements ED, and the contact electrode 700.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A method for manufacturing a light emitting element, comprising:
forming a first semiconductor structure including:
a first semiconductor layer doped with a first conductivity type dopant disposed on a base substrate;
a light emitting layer disposed on the first semiconductor layer; and
a second semiconductor layer disposed on the light emitting layer and doped with a second conductivity type dopant;
forming a second semiconductor structure spaced apart from another second semiconductor structure on the base substrate by etching the first semiconductor structure in a direction perpendicular to a surface of the base substrate; and
activating a second conductivity type dopant in the second semiconductor layer of the second semiconductor structure to form a light emitting element core.

2. The method of claim 1, wherein the activating of the second conductivity type dopant comprises performing an annealing process.

3. The method of claim 2, wherein the annealing process comprises performing heat treatment on the second semiconductor layer in a temperature range of about 450° C. to about 750° C.

4. The method of claim 2, wherein the annealing process comprises performing heat treatment on the second semiconductor layer in a temperature range of about 170° C. to about 550° C.

5. The method of claim 1, wherein the first semiconductor structure further comprises an element electrode layer disposed on the second semiconductor layer.

6. The method of claim 1, wherein
the first conductivity type is an n type, and
the second conductivity type is a p type.

7. The method of claim 6, wherein a hydrogen concentration of the second semiconductor layer of the light emitting element core has a concentration gradient increasing from a side surface of the second semiconductor layer toward a center of the second semiconductor layer.

8. The method of claim 6, wherein the hydrogen concentration of the second semiconductor layer of the light emitting element core is about 1×10¹⁹/cm³ or less.

9. The method of claim 1, wherein a doping amount of the second conductivity type dopant doped into the second semiconductor layer of the first semiconductor structure is in a range of about 1.0×10¹⁹/cm³ to about 1.26×10¹⁹/cm³.

10. The method of claim 1, wherein a side surface of the first semiconductor layer of the second semiconductor structure and a side surface of the second semiconductor layer of the second semiconductor structure are aligned in a line.

11. A method for manufacturing a light emitting element, comprising:
forming a first semiconductor structure including:
a first semiconductor layer doped with a first conductivity type dopant disposed on a base substrate;
a light emitting layer disposed on the first semiconductor layer; and
a second semiconductor layer disposed on the light emitting layer and doped with a second conductivity type dopant;
activating a second conductivity type dopant in the second semiconductor layer of the first semiconductor structure to form a second semiconductor structure; and
forming a plurality of light emitting element cores spaced apart from each other on the base substrate by etching the second semiconductor structure in a direction perpendicular to a surface of the base substrate,
wherein a doping amount of the second conductivity type dopant doped into the second semiconductor layer of the first semiconductor structure is about 1.0×10¹⁹/cm³ or less.

12. The method of claim 11, wherein the activating of the second conductivity type dopant comprises performing heat treatment on the second semiconductor layer in a temperature range of about 450° C. to about 750° C.

13. The method of claim 11, wherein
the first conductivity type is an n type, and the
second conductivity type is a p type.

14. The method of claim 11, wherein an amount of the second conductivity type dopant in the second semiconductor layer of the light emitting element core is about 1.0×10¹⁹/cm³ or less.

15. The method of claim 11, wherein a side surface of the first semiconductor layer of the light emitting element core and a side surface of the second semiconductor layer of the light emitting element core are aligned in a line.

16. A light emitting element, comprising:
a first semiconductor layer having a first conductivity type;
a second semiconductor layer disposed on the first semiconductor layer and having a second conductivity type; and
a light emitting layer disposed between the first semiconductor layer and the second semiconductor layer, wherein
the light emitting element extends in a direction,
a side surface of the first semiconductor layer and a side surface of the second semiconductor layer are aligned in a line, and
in a cross-sectional view perpendicular in the direction to the second semiconductor layer, a concentration of hydrogen included in the second semiconductor layer has a concentration gradient increasing from a side surface of the second semiconductor layer to a center of the second semiconductor layer.

17. The light emitting element of claim 16, wherein a hydrogen concentration of the second semiconductor layer is about 1×10¹⁹/cm³ or less.

18. The light emitting element of claim 16, wherein
the first conductivity type is an n type, and
the second conductivity type is a p type.

19. The light emitting element of claim 16, wherein
the first semiconductor layer is doped with a first conductivity type dopant,
the second semiconductor layer is doped with a second conductivity type dopant, and
an amount of the second conductivity type dopant doped into the second semiconductor layer is about 1.0×10¹⁹/cm³ or less.

20. The light emitting element of claim 16, wherein an angle between the side surface of the second semiconductor layer and the side surface of the first semiconductor layer is about 20° or less.
